(19) United States
(12) Patent Application Publication
(10) Pub. No.: US 2013/0127879 A1
(43) Pub. Date: May 23, 2013

(54) GLASS-ENCAPSULATED PRESSURE SENSOR

(71) Applicants: David William Burns, San Jose, CA (US); Philip Jason Stephanou, Mountain View, CA (US); Ravindra V. Shenoy, Dublin, CA (US); Kurt Edward Petersen, Milpitas, CA (US)

(72) Inventors: David William Burns, San Jose, CA (US); Philip Jason Stephanou, Mountain View, CA (US); Ravindra V. Shenoy, Dublin, CA (US); Kurt Edward Petersen, Milpitas, CA (US)

(73) Assignee: QUALCOMM MEMS TECHNOLOGIES, INC., San Diego, CA (US)

(21) Appl. No.: 13/299,645

(22) Filed: Nov. 18, 2011

(51) Int. Cl. G06T 1/00; H01L 21/02; H05K 13/00; H01L 29/84

(52) U.S. Cl. 345/501; 257/417; 438/51; 29/729; 257/E29.324; 257/E21.002

(57) ABSTRACT

This disclosure provides systems, methods and apparatus for glass-encapsulated pressure sensors. In one aspect, a glass-encapsulated pressure sensor may include a glass substrate, an electromechanical pressure sensor, an integrated circuit device, and a cover glass. The cover glass may be bonded to the glass substrate with an adhesive, such as epoxy, glass frit, or a metal bond ring. The cover glass may have any of a number of configurations. In some configurations, the cover glass may partially define a port for the electromechanical pressure sensor at an edge of the glass-encapsulated pressure sensor. In some configurations, the cover glass may form a cavity to accommodate the integrated circuit device that is separate from a cavity that accommodates the electromechanical pressure sensor.

### TECHNICAL FIELD

This disclosure relates to structures and processes for glass packaging of electromechanical systems and integrated circuit devices.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term interferometric modulator or interferometric light modulator refers to a device that selectively absorbs and/or reflects light using the principles of optical interference. In some implementations, an IMOD may include a pair of conductive plates, one or both of which may be transparent and/or reflective, wholly or in part, and capable of relative motion upon application of an appropriate electrical signal. For example, one plate may include a stationary layer deposited on a substrate and the other plate may include a reflective membrane separated from the stationary layer by an air gap. The position of one plate in relation to another can change the optical interference of light incident on the IMOD. IMOD devices have a wide range of applications, and are anticipated to be used in improving existing products and creating new products, especially those with display capabilities.

Another type of EMS device is a pressure sensor. A pressure sensor measures pressure of a fluid and transduces the measured pressure into a signal.

### SUMMARY

The systems, methods and devices of the disclosure each have several innovative aspects, no single one of which is solely responsible for the desirable attributes disclosed herein.

One innovative aspect of the subject matter described in this disclosure can be implemented in a glass-encapsulated pressure sensor that includes a glass substrate, an electromechanical pressure sensor, and a cover glass. The cover glass may be bonded to the glass substrate with an adhesive, such as epoxy, glass frit, or a metal bond ring. The cover glass may have any of a number of configurations. For example, in some implementations, the cover glass may partially define a port for the electromechanical pressure sensor at an edge of the glass-encapsulated pressure sensor. In some implementations, the cover glass may form a cavity to accommodate the electromechanical pressure sensor. The glass-encapsulated pressure sensor may further include an integrated circuit device. In some implementations, the cover glass may form a cavity to accommodate the integrated circuit device that is separate from a cavity that accommodates the electromechanical pressure sensor.

Another innovative aspect of the subject matter described in this disclosure can be implemented in an apparatus including a glass substrate, an electromechanical pressure sensor, and a cover glass bonded to the surface of the glass substrate with a joining ring. The electromechanical pressure sensor can be disposed on a surface of the glass substrate. The cover glass can include a first recess that forms a first cavity when the cover glass is bonded to the surface of the glass substrate and which can be configured to accommodate the electromechanical pressure sensor. The apparatus can include one or more ports that provide fluidic access to the pressure sensor. A port can be formed, for example, in one or more of the glass substrate, the joining ring, or the cover glass. In some implementations, the port can be at least partially defined by a recess in the glass substrate or the cover glass or by one or more channels in the joining ring. Also in some implementations, the joining ring can include at least one of a metal bond ring, an epoxy, or a glass frit. In some implementations, an integrated circuit device configured to sense output from the electromechanical pressure sensor can be disposed on the surface of the glass substrate. The apparatus can further include bond pads on a surface of the cover glass or the glass substrate that are configured to attach to a flexible connector.

The apparatus may include a display and a processor that is configured to communicate with the display. The processor may be configured to process image data. The apparatus may include a memory device that is configured to communicate with the processor. The apparatus may include a driver circuit configured to send at least one signal to the display and a controller configured to send at least a portion of the image data to the driver circuit. The apparatus may include an image source module configured to send the image data to the processor. The image source module may include at least one of a receiver, transceiver, and transmitter. The apparatus may include an input device configured to receive input data and to communicate the input data to the processor.

Another innovative aspect of the subject matter described in this disclosure can be implemented in an apparatus including means for encapsulating an electromechanical pressure sensor inside a package, means for transmitting a fluidic pressure from an outside of the package to the electromechanical pressure sensor, means for converting a fluidic pressure within the electromechanical pressure sensor into an electrical signal, and means for transmitting an electrical signal from the electromechanical pressure sensor to the exterior of the package. In some implementations, the apparatus can include means for conditioning the electrical signal generated by the electromechanical pressure sensor. In some implementations, the apparatus can include means for hermetically sealing an integrated circuit device encapsulated inside the package.

Yet another innovative aspect of the subject matter described in this disclosure can be implemented in a method for fabricating a glass-encapsulated pressure sensor. The method can include bonding a cover glass to a surface of a glass substrate. An electromechanical pressure sensor can be disposed on the surface of the glass substrate. An integrated circuit device configured to sense output from the electromechanical pressure sensor also can be disposed on the surface of the glass substrate. The cover glass can include a recess that forms a cavity when the cover glass is bonded to the surface of the glass substrate. The cavity can be configured to accommodate the electromechanical pressure sensor. In some implementations, the bonding is performed with at least one of a metal bond ring or an epoxy.

Details of one or more implementations of the subject matter described in this specification are set forth in the accompanying drawings and the description below. Although the examples provided in this disclosure are primarily described in terms of electromechanical systems (EMS) and microelectromechanical systems (MEMS)-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 IMOD display.

FIG. 3 shows an example of a diagram illustrating movable reflective layer position versus applied voltage for the IMOD of FIG. 1.

FIG. 4 shows an example of a table illustrating various states of an IMOD when various common and segment voltages are applied.

FIG. 5A shows an example of a diagram illustrating a frame of display data in the 3×3 IMOD display of FIG. 2.

FIG. 5B shows an example of a timing diagram for common and segment signals that may be used to write the frame of display data illustrated in FIG. 5A.

FIG. 6A shows an example of a partial cross-section of the IMOD display of FIG. 1.

FIGS. 6B-6E show examples of cross-sections of varying implementations of IMODs.

FIG. 7 shows an example of a flow diagram illustrating a manufacturing process for an IMOD.

FIGS. 8A-8E show examples of cross-sectional schematic illustrations of various stages in a method of making an IMOD.

FIGS. 9A-10B show examples of varying views of glass-encapsulated pressure sensors including a side port.

FIGS. 11A-12B show examples of varying views of glass-encapsulated pressure sensors including multiple cavities.

FIGS. 13A-14B show examples of varying views of glass-encapsulated pressure sensors including a metal bond ring.

FIGS. 15A-16B show examples of varying views of glass-encapsulated pressure sensors including a sensor-protecting feature.

FIGS. 17A-18B show examples of varying views of a glass-encapsulated pressure sensor including a port extending through a cover glass.

FIGS. 19A and 19B show examples of varying views of a glass-encapsulated pressure sensor including a port extending through a glass substrate.

FIGS. 20A-21B show examples of varying views of a glass-encapsulated pressure sensor configured to connect to a flexible connector.

FIG. 22 shows an example of a flow diagram illustrating a manufacturing process for a glass-encapsulated pressure sensor.

FIGS. 23A and 23B show examples of system block diagrams illustrating a display device that includes a plurality of IMODs.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to glass-encapsulated pressure sensors. In some implementations, a glass-encapsulated pressure sensor includes a glass substrate, an electromechanical pressure sensor, and a cover glass. The cover glass may be bonded to the glass substrate with an adhesive, such as epoxy, glass frit, or a metal bond ring. The pressure sensor can be encapsulated between the glass substrate and the cover glass. In some implementations, the glass-encapsulated pressure sensor includes an integrated circuit device that is configured to condition signals generated by the pressure sensor. The integrated circuit device also may be encapsulated between the glass substrate and the cover glass. The glass-encapsulated pressure sensor can include a pressure port in a side surface, top surface or bottom surface of a package formed by joining a cover glass and glass substrate, or in an interface between the cover glass and glass substrate.

The cover glass may have any of a number of configurations. For example, the cover glass may include a recess that forms a cavity when the cover glass is bonded to the surface of the glass substrate. The recess also may form a port at an edge of the glass-encapsulated pressure sensor, with the port providing an opening that may allow a fluidic pressure to interact with the electromechanical pressure sensor. As another example, the cover glass may include two recesses that form two cavities when the cover glass is bonded to the surface of the glass substrate. One cavity may accommodate the integrated circuit device, and one cavity may accommodate the electromechanical pressure sensor. In another example, a cover glass can include a port extending through a thickness of the cover glass. Further configurations of the cover glass are described herein.

The glass substrate may have any of a number of configurations. For example, the glass substrate may include an etched recess that forms a reference cavity of a pressure sensor when a pressure-deformable diaphragm is suspended over it. The glass substrate may include a port extending through the thickness of the glass substrate. Further configurations of the glass substrate are described herein.

In some implementations, the glass-encapsulated pressure sensor can include through-glass vias extending through the cover glass and/or glass substrate. Through-glass vias can provide an electrical pathway between the interior and the exterior of the glass-encapsulated pressure sensor.

Particular implementations of the subject matter described in this disclosure can be implemented to realize one or more of the following potential advantages. Generally, a glass-encapsulated pressure sensor can provide a low cost, small size, low profile, and low power consumption pressure sensor. In some implementations, the glass-encapsulated pressure sensor can be incorporated into cellular phones and other mobile devices and can be used, for example, to determine altitude and augment GPS systems.

Further, pressure sensors that are fabricated on glass substrates are generally compatible with displays and other devices that are also fabricated on glass substrates, as the pressure sensors can either be fabricated jointly with the other devices or attached as a separate device, having well-matched thermal expansion properties. The materials employed result in a high thermal budget that enables reflow or wave soldering to attach the device to a printed circuit board or other substrate. In some implementations, the glass-encapsulated pressure sensor includes electronic circuitry. Electronic circuitry can be fabricated on silicon, with the silicon die thinned and attached to a glass substrate having an electromechanical pressure sensor formed thereon, providing a short signal path between the silicon die and the pressure sensing element. In some implementations, the electronic circuitry can be fabricated directly on the glass substrate along with the pressure sensing element, and both encapsulated together in one or more cavities within the glass package.

Fabrication of the electronic circuitry or otherwise disposing integrated circuit devices on the surface of a glass substrate along with the pressure sensing element allows a short signal path between the sensing element and the circuitry, minimizing the impact of noise and interference on the signal lines and resulting in a cleaner output signal. In some implementations, the output signal may be an amplified analog signal or a digital signal. Encapsulation of the integrated circuit devices and the pressure sensing element in a glass package provides environmental protection, as glass is inert to most pressure media such as air or many liquids. The glass lid and glass substrate of a joined pressure sensor are thermally well matched, minimizing pressure hysteresis effects that can plague packages with dissimilar materials. One or more pressure ports in the top, sides, bottom, or within the joining ring provides flexibility when mounting the sensor, such as when mounting in a cell phone for barometric pressure measurements. Through-glass vias in some implementations allow direct connection of the packaged pressure sensor to a printed circuit or wiring board. In some implementations, a flexible connector is attachable to the glass-encapsulated pressure sensor, allowing electrical connection with a PCB while allowing the pressure sensor to be positioned near an exterior wall of an enclosure such as a cell phone case. The processes employed to create and encapsulate the pressure sensing element are amenable to batch fabrication processes, which enables low cost wafer- or panel-level manufacturing.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

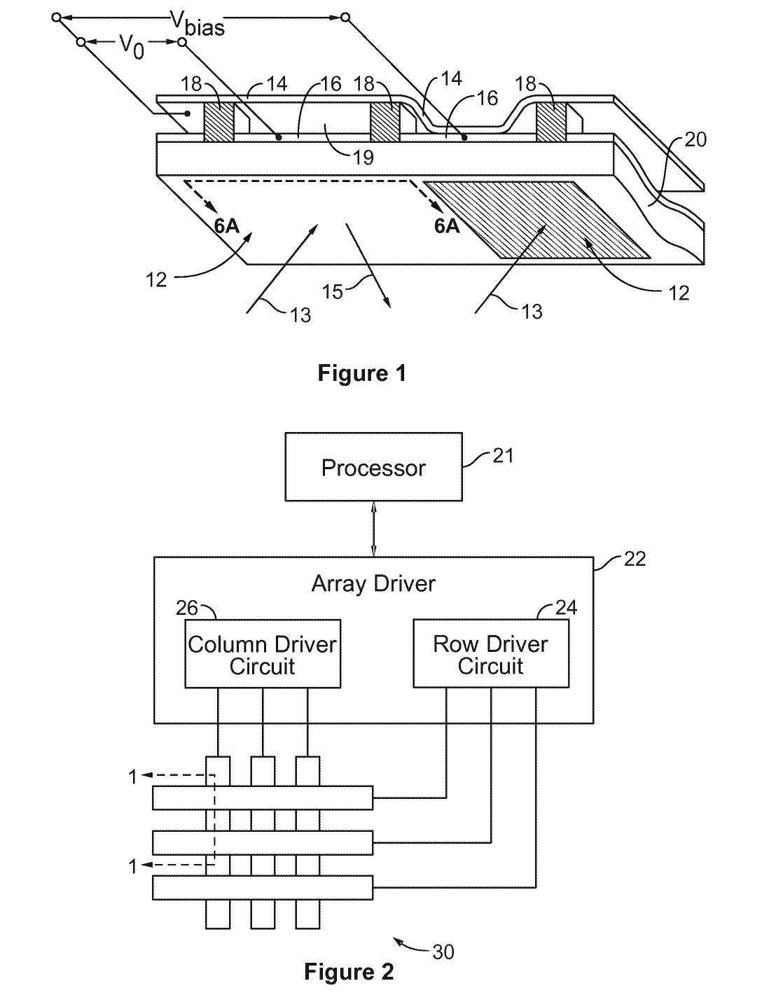

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be approximately less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 IMOD display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

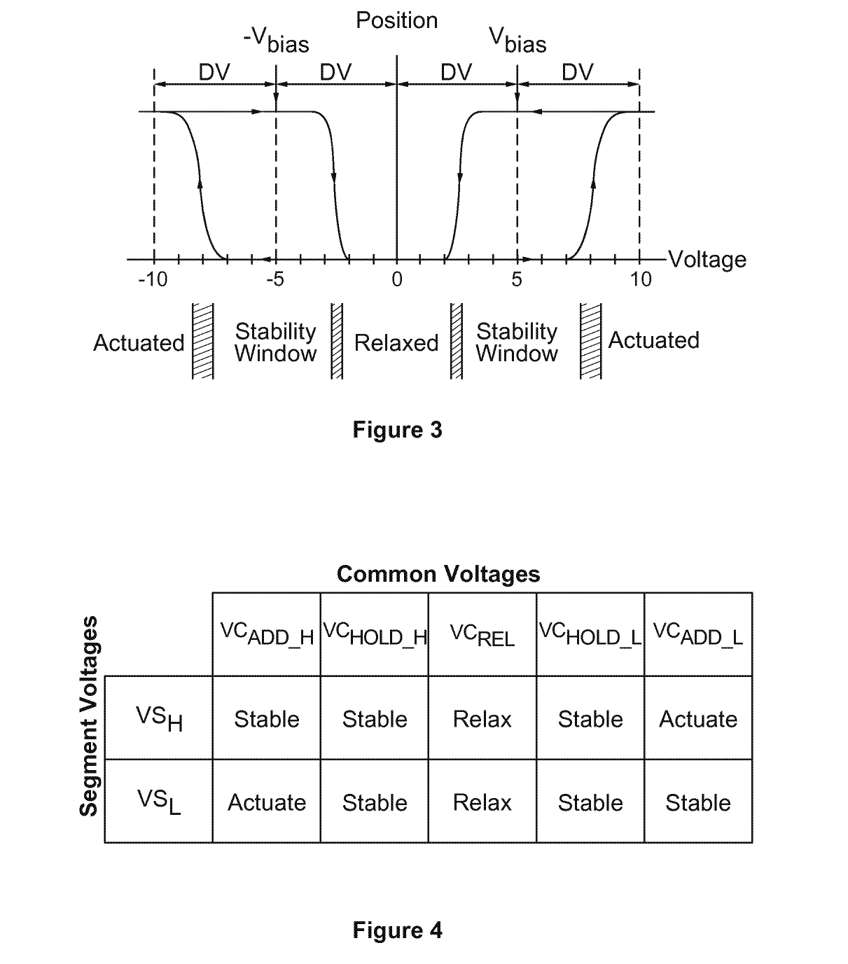

FIG. 3 shows an example of a diagram illustrating movable reflective layer position versus applied voltage for the IMOD of FIG. 1. For MEMS interferometric modulators, the row/column (i.e., common/segment) write procedure may take advantage of a hysteresis property of these devices as illustrated in FIG. 3. An interferometric modulator may use, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an IMOD when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

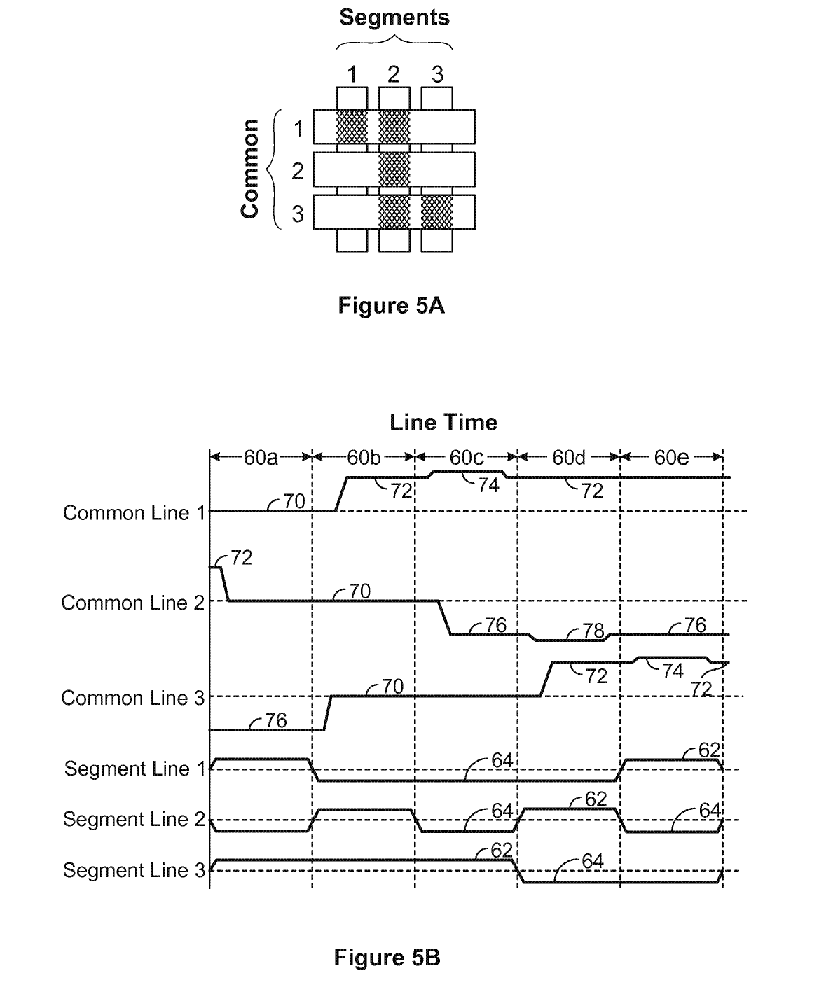

As illustrated in FIG. 4 (as well as in the timing diagram shown in FIG. 5B), when a release voltage VCREL is applied along a common line, all interferometric modulator elements along the common line will be placed in a relaxed state, alternatively referred to as a released or unactuated state, regardless of the voltage applied along the segment lines, i.e., high segment voltage VSH and low segment voltage VSL. In particular, when the release voltage VCREL is applied along a common line, the potential voltage across the modulator (alternatively referred to as a pixel voltage) is within the relaxation window (see FIG. 3, also referred to as a release window) both when the high segment voltage VSH and the low segment voltage VSL are applied along the corresponding segment line for that pixel.

When a hold voltage is applied on a common line, such as a high hold voltage VCHOLD_H or a low hold voltage VCHOLD_L, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VSH and the low segment voltage VSL are applied along the corresponding segment line. Thus, the segment voltage swing, i.e., the difference between the high VSH and low segment voltage VSL, is less than the width of either the positive or the negative stability window.

When an addressing, or actuation, voltage is applied on a common line, such as a high addressing voltage VCADD_H or a low addressing voltage VCADD_L, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VCADD_H is applied along the common line, application of the high segment voltage VSH can cause a modulator to remain in its current position, while application of the low segment voltage VSL can cause actuation of the modulator. As a corollary, the effect of the segment voltages can be the opposite when a low addressing voltage VCADD_L is applied, with high segment voltage VSH causing actuation of the modulator, and low segment voltage VSL having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 IMOD display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VCREL—relax and VCHOLD_L—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

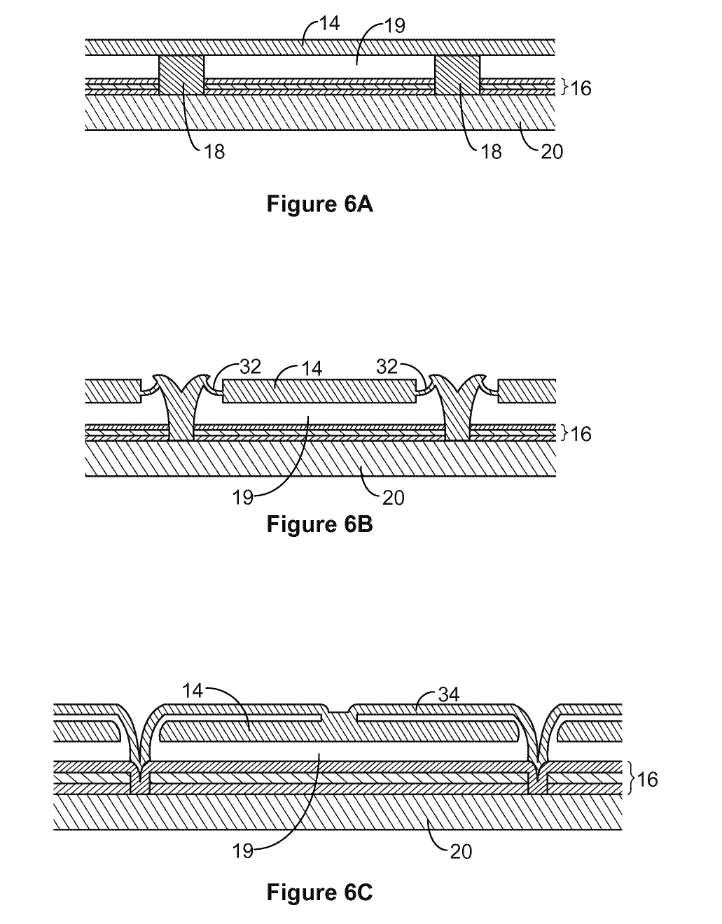

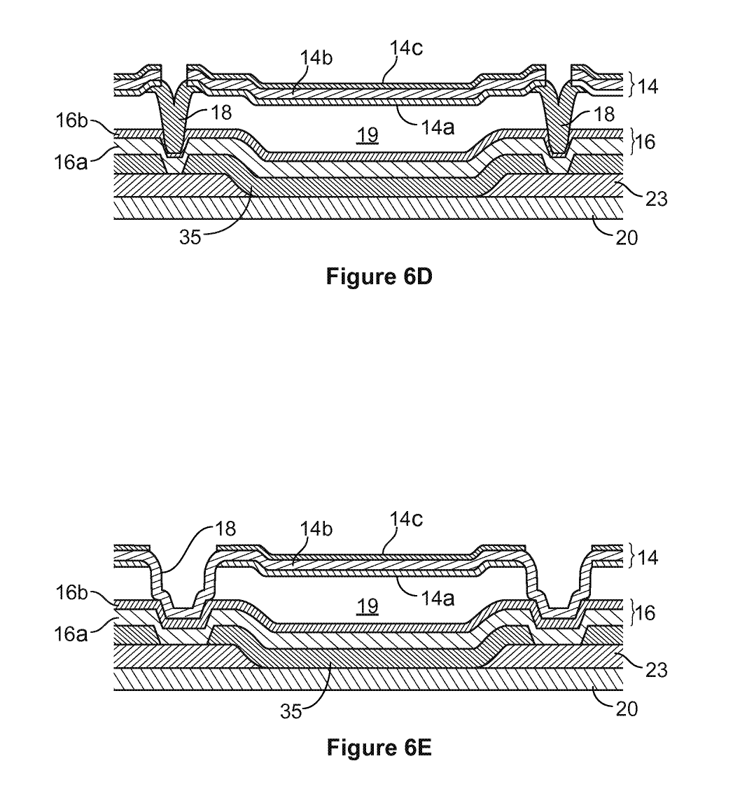

The details of the structure of interferometric modulators that operate in accordance with the principles set forth above may vary widely. For example, FIGS. 6A-6E show examples of cross-sections of varying implementations of IMODs, including the movable reflective layer 14 and its supporting structures. FIG. 6A shows an example of a partial cross-section of the IMOD display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO2). In some implementations, the support layer 14b can be a stack of layers, such as, for example, a SiO2/SiON/SiO2 tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO2 layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF4) and/or oxygen (O2) for the MoCr and SiO2 layers and chlorine (C12) and/or boron trichloride (BC13) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as patterning.

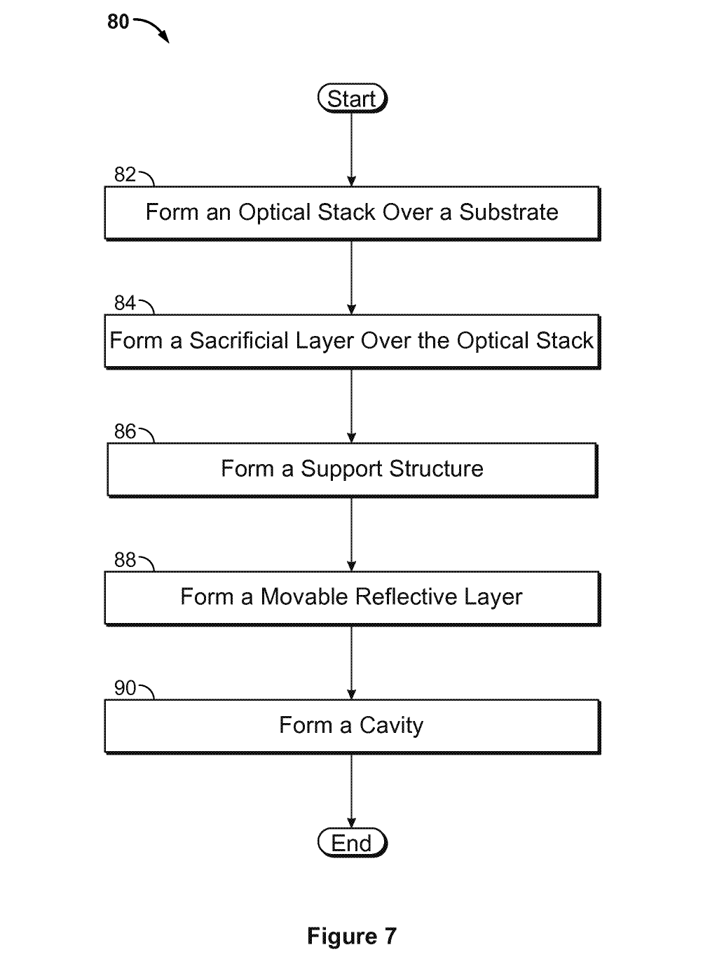

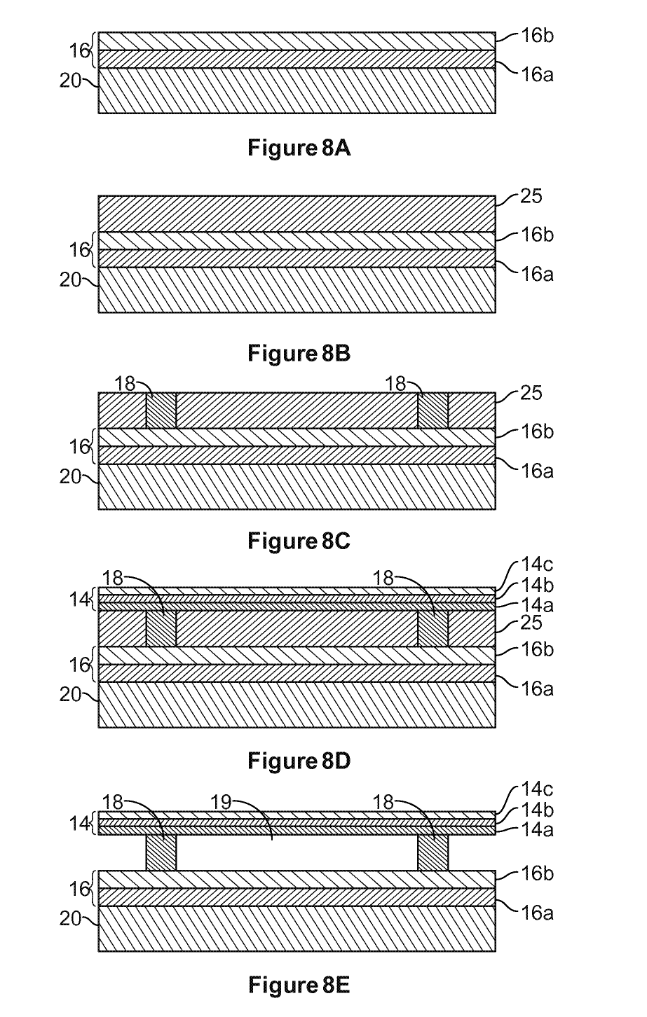

FIG. 7 shows an example of a flow diagram illustrating a manufacturing process 80 for an IMOD, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF2)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF2 for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Another example of an electromechanical systems (EMS) device is a pressure sensor. A pressure sensor is a transducer that measures pressure and converts the measurement into an output signal, such as an electrical output signal. In some implementations, one, two, or multiple pressure sensors may be mounted, joined or otherwise connected to one or more EMS devices, such as an IMOD display device. In some implementations, one, two, or multiple pressure sensors may be fabricated as part of an IMOD display device.

In some implementations, a glass-encapsulated pressure sensor includes an electromechanical pressure sensor fabricated or otherwise disposed on a glass substrate, a cover glass bonded to the glass substrate to encapsulate the pressure sensor, and a pressure port that provides fluid (gas or liquid) access to the pressure sensor. The pressure sensor can be configured to perform any type of pressure measurement including absolute, gauge, and differential measurements. The pressure sensor can be an electromechanical systems (EMS) pressure sensor. In some implementations, the pressure sensor is configured to measure static fluid systems. In some implementations, the pressure sensor may be configured to measure slowly changing pressures such as barometric pressure. In some implementations, the pressure sensor may be configured to measure quickly changing pressures, such as pressure differences across a pitot tube to determine air speed. In some implementations, the pressure sensor is an EMS or MEMS capacitive pressure sensor. Capacitive pressure sensors generally include two electrodes, a fixed electrode and a flexible membrane electrode that deflects in response to applied fluidic pressure. Deflections due to applied fluidic pressure on the membrane are measured by the change in capacitance between the two electrodes. While the description below refers to EMS or MEMS capacitive pressure sensors, it is understood that other types of pressure sensors can be used including EMS or MEMS piezoresistive or strain gauge pressure sensors and EMS or MEMS piezoelectric pressure sensors. In some implementations, a glass-encapsulated pressure sensor includes electronic circuitry configured to condition an electrical signal generated by the pressure sensor.

Implementations of the glass-encapsulated pressure sensor include a glass substrate, a cover glass, one or more pressure sensors encapsulated between the glass substrate and the cover glass, a port configured to allow fluid access to the pressure sensor, and one or more electrical connections between the one or more pressure sensors and an exterior of the glass-encapsulated pressure sensor. In some implementations, the glass-encapsulated pressure sensor includes an integrated circuit device encapsulated between the glass substrate and cover glass. The integrated circuit device can be configured to condition a signal received from the one or more pressure sensors.

In some implementations, a length of the cover glass may be about 1 to 5 mm, and a width of the cover glass may be about 1 to 5 mm. In some implementations, the length and the width of the cover glass may be the same or approximately the same as the length and the width of the glass substrate. In various implementations, the cover glass can be about 50 to 700 microns thick, about 100 to 300 microns thick, about 300 to 500 microns thick, or about 500 microns thick. The cover glass may be or include, for example, a borosilicate glass, a soda lime glass, quartz, Pyrex, or other suitable glass material. The cover glass may be transparent or non-transparent. For example, the cover glass may be frosted, coated, painted, or otherwise made opaque.

In some implementations, a length of the glass substrate may be about 1 to 5 mm, and a width of the substrate may be about 1 to 5 mm. In various implementations, the glass substrate can be about 50 to 700 microns thick, about 100 to 300 microns thick, about 300 to 500 microns thick, or about 500 microns thick. The glass substrate may be or include, for example, a borosilicate glass, a soda lime glass, quartz, Pyrex, or other suitable glass material. The glass substrate may be transparent or non-transparent. For example, the glass substrate may be frosted, coated, painted, or otherwise made opaque.

In some implementations, the length and/or the width of the cover glass may be the same or approximately the same as the length and/or the width of the glass substrate. In some implementations, the length and/or the width of the cover glass may be different than the length and/or the width of the glass substrate. For example, in some implementations, one or the other of the cover glass and glass substrate has a dimension larger than the corresponding dimension of the cover glass and glass substrate such that the glass- encapsulated pressure sensor includes a ledge.

In some implementations, a cover glass is a generally planar substrate having two major substantially parallel surfaces connected by side surfaces. In some implementations, all or a portion of one major surface of a cover glass is an interior surface of the glass-encapsulated pressure sensor, with all or a portion of the other major surface being an exterior surface of the glass-encapsulated pressure sensor. In some implementations, a glass substrate is a generally planar substrate having two major substantially parallel surfaces connected by side surfaces. In some implementations, all or a portion of one major surface of a glass substrate is an interior surface of the glass-encapsulated pressure sensor, with all or a portion of the other major surface being an exterior surface of the glass-encapsulated pressure sensor. One or both of a cover glass and a glass substrate can include one or more recesses in an interior surface to accommodate a pressure sensor and/or an integrated circuit device.

An interior surface of a glass substrate can be joined to an interior surface of the cover glass. The cover glass and glass substrate can be joined with an interface such as an epoxy, a glass frit, or a metal. In some implementations, a joined cover glass and glass substrate forms a glass package to encapsulate the pressure sensor. The glass package can include one or more sides. In some implementations, a glass package includes a first surface that is an exterior surface of a cover glass, a second surface that is an exterior surface of a glass substrate, and one or more sides between the first and second surfaces.

A pressure port configured to provide fluid access to a pressure sensor can be formed in one or more of a cover glass, a glass substrate, and an interface between a cover glass and a glass substrate. In some implementations, a port is at least partially defined by an interior surface of a cover glass and/or of a glass substrate. In some implementations, a port is at least partially defined by a recess in an interior surface of a cover glass and/or of a glass substrate. In some implementations, the recess may extend to a side of the cover glass or glass substrate. In some implementations, a port includes one or more channels through an interface such as a joining ring positioned between a cover glass and a glass substrate. The joining ring may include one or more channels through an epoxy, glass frit or metal ring. In some implementations, a port is formed in an exterior surface of a cover glass or glass substrate.

In some implementations, a port can include a fence positioned between a pressure sensor and an external environment to protect the pressure sensor. In some implementations, dimensions of a port opening can be between a few tenths of a micron and several millimeters.

An electrical connection between a device and an exterior of a glass package encapsulating a pressure sensor can include any electrical component, including conductive traces (also referred to as conductive lines or leads), conductive vias and conductive pads. Conductive traces can be formed on one or more surfaces of a cover glass and/or glass substrate, including on any interior, exterior or side surface. Conductive lines and vias can be formed in one or more of a cover glass and a glass substrate. In some implementations, an electrical connection includes a through-glass via interconnect that extends from an interior surface of a cover glass to an exterior surface of the cover glass. In some implementations, an electrical connection includes a through-glass via that extends from an interior surface of a glass substrate to an exterior surface of the glass substrate.

Conductive pads, also referred to as bond pads or contact pads, can be formed on one or more surfaces of a cover glass and/or glass substrate, including on any interior, exterior or side surface. In some implementations, a glass-encapsulated pressure sensor includes one or more conductive pads on an exterior surface to which a connection can be wire bonded, soldered, or flip-chip attached and that can be configured for connection to external components such as printed circuit boards (PCBs), ICs, passive components and the like. In some implementations, a glass-encapsulated pressure sensor includes one or more conductive pads configured to provide a connection point for a flexible connector. A glass-encapsulated pressure sensor can include one or more electrically inactive, or dummy, bond pads on an exterior surface that are configured to bond to dummy solder balls or other electrically inactive joints.

In some implementations, an electrical connection between the pressure sensor and an exterior of the glass-encapsulated pressure sensor includes an electrical connection from a pressure sensor to an integrated circuit device and from an integrated circuit device to the exterior of the glass-encapsulated pressure sensor. In some implementations, an integrated circuit device performs signal processing on output sensed from the electromechanical pressure sensor. In some implementations, the integrated circuit device may be an application-specific integrated circuit (ASIC).

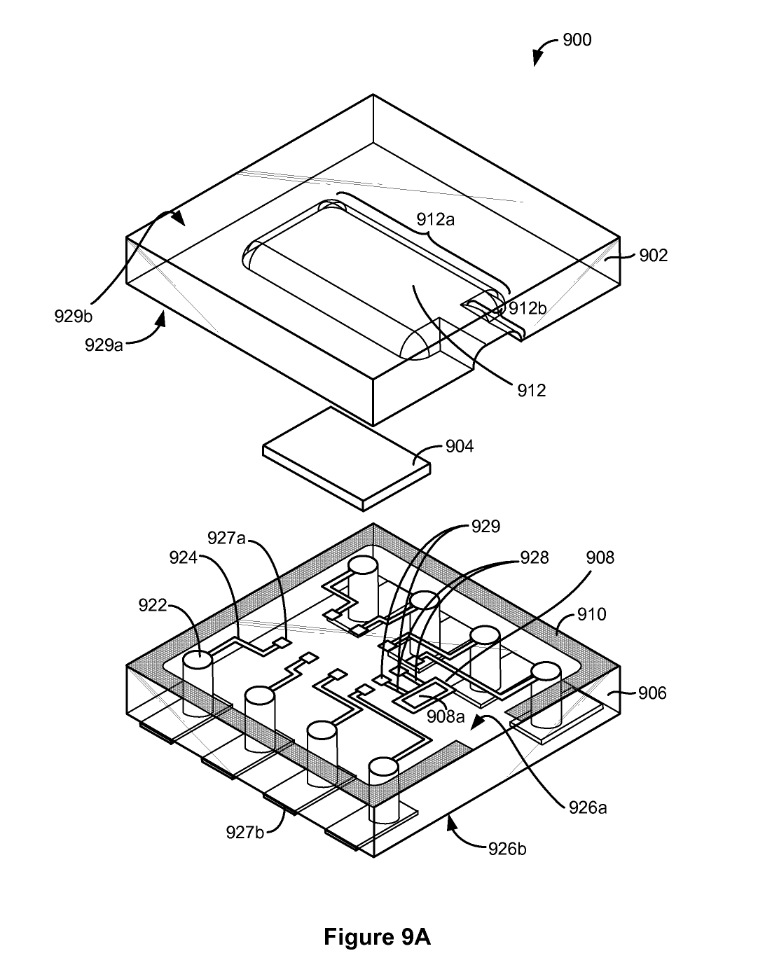

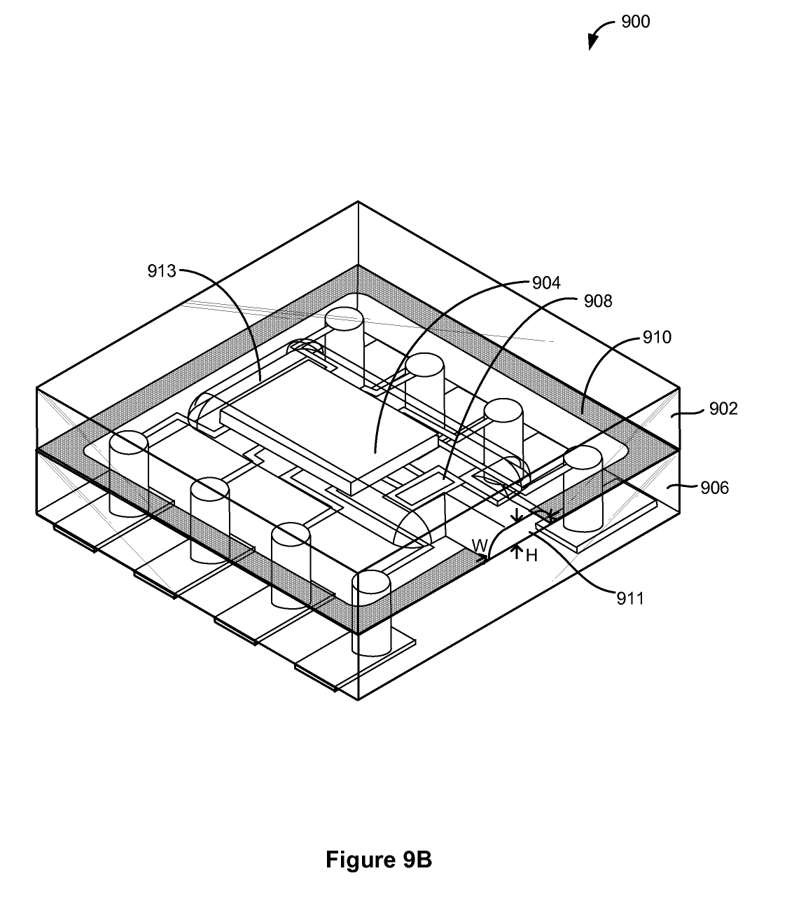

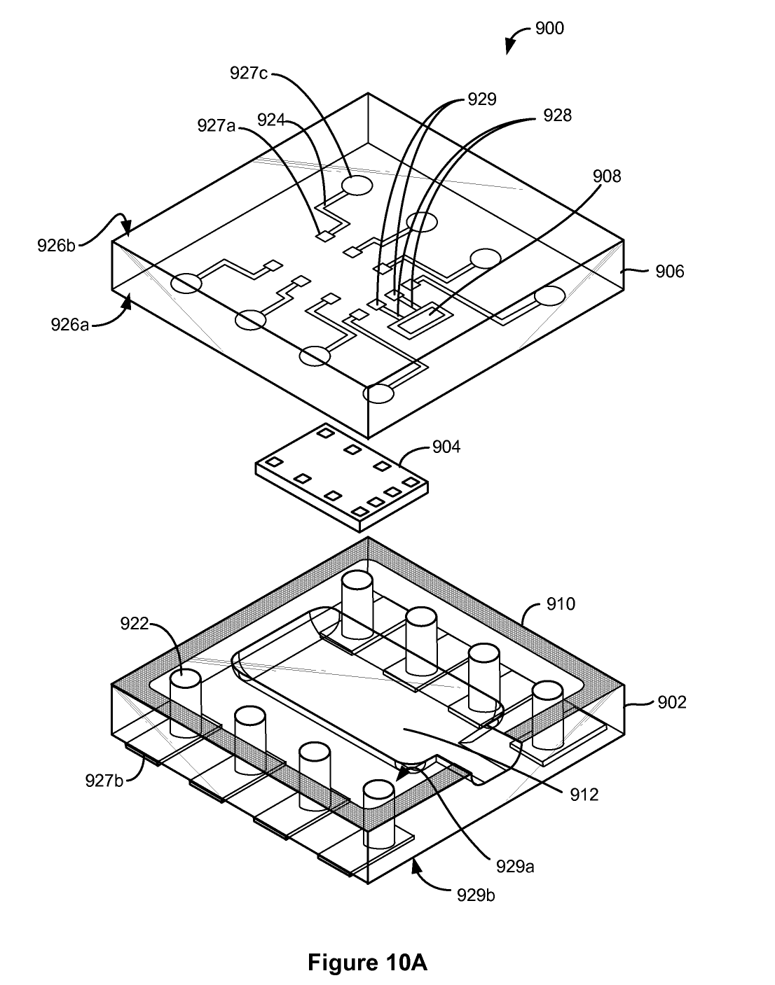

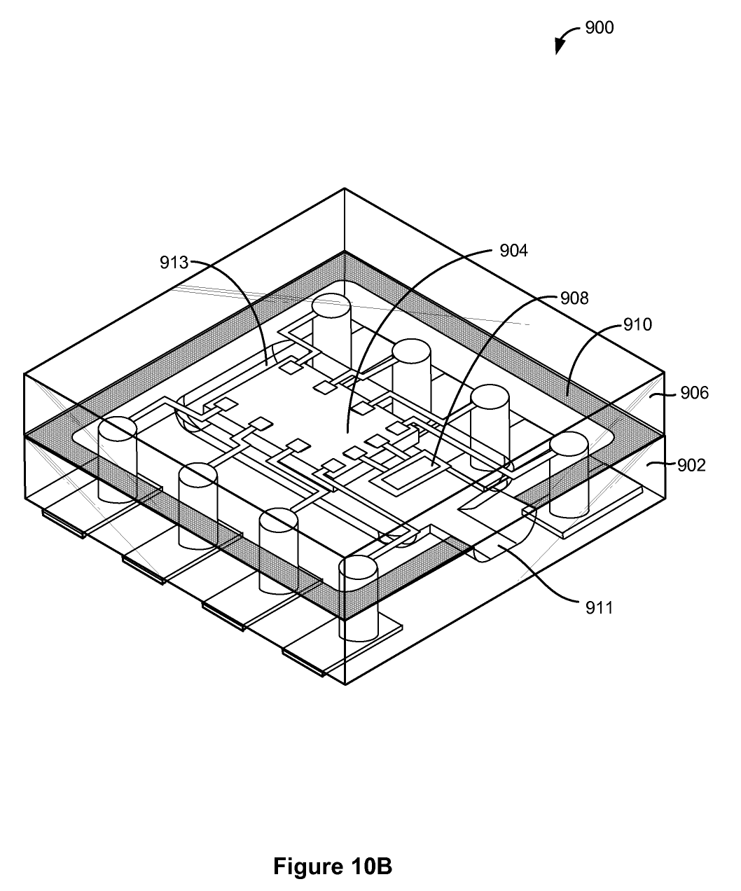

Examples of various features of implementations of a glass-encapsulated pressure sensor are described below with reference to FIGS. 9A-21B. FIGS. 9A-10B show examples of varying views of glass-encapsulated pressure sensors including a side port. First, FIG. 9A shows an example of an exploded view diagram of the glass-encapsulated pressure sensor. FIG. 9B shows an example of a simplified isometric view of the glass-encapsulated pressure sensor shown in FIG. 9A. For clarity, some components shown in FIG. 9A are not shown in FIG. 9B.

The glass-encapsulated pressure sensor 900 shown in the example of FIGS. 9A and 9B includes a cover glass 902, an integrated circuit device 904, a glass substrate 906, an electromechanical pressure sensor 908, and a joining ring 910. While the cover glass 902 and the glass substrate 906 are depicted as transparent in these and the remaining associated Figures, the cover glass and the glass substrate may be transparent or non-transparent. For example, the cover glass and the glass substrate may be frosted, coated, painted, or otherwise made opaque.

The cover glass 902 is substantially planar, having two major substantially parallel surfaces, an interior surface 929a and an exterior surface 929b. The cover glass 902 includes a recess 912 in interior surface 929a in the example of FIG. 9A. When the cover glass 902 is bonded to the glass substrate 906, a cavity 913 is formed as shown in the example of FIG. 9B. With respect to glass-encapsulated pressure sensors, a cavity is an open volume in a glass-encapsulated pressure sensor that may accommodate different components of the glass-encapsulated pressure sensor. The cavity 913 in the example of FIGS. 9A and 9B accommodates the integrated circuit device 904 and the electromechanical pressure sensor 908.

The recess 912 includes a main portion 912a to accommodate the integrated circuit device 904 and the electromechanical pressure sensor 908, and a narrow portion 912b that extends to a side of the cover glass 902. When the cover glass 902 is bonded to the glass substrate 906, a side port 911 is formed, as shown in the example of FIG. 9B. The side port 911 allows fluid access to the electromechanical pressure sensor 908. Fluid access allows a gas and/or liquid fluid to reach and interact with the pressure sensor 908, allowing the pressure sensor 908 to measure pressure of the fluid.

The depth of the recess 912 in the cover glass 902 is sufficient to accommodate the integrated circuit device 904 and the pressure sensor 908. In implementations such as that shown in the example of FIGS. 9A and 9B, in which an integrated circuit device is a silicon die or otherwise separately packaged, the thickness of the integrated circuit device can be between 100 to 300 microns, for example. Thicker or thinner integrated circuit devices also can be used according to the desired implementation.

In the example of FIGS. 9A and 9B, the recess 912 has a uniform depth such that the narrow portion 912b is the same depth as main portion 912a. In alternate implementations, the depths of the main portion 912a and the narrow portion 912b can differ. In some implementations, the dimensions of a recess at an edge of the cover glass determine dimensions of a side port. In the example of FIG. 9A, the depth and width of the narrow portion 912b determine the height and width, respectively, of an opening of the side port 911. A height H and width W of the side port 911 are labeled in FIG. 9B. The dimensions of the side port 911 are sufficient to allow fluid access to and equilibration at pressure sensor 908. When the cover glass 902 is bonded to the glass substrate 906, the side port 911 may be about 2 to 300 microns high in some implementations. A side port width may be about 5 microns to about one-half the width or length of the cover glass in some implementations.

The integrated circuit device 904 can be configured to sense output from the electromechanical pressure sensor 908 and is disposed on the glass substrate 906. In some implementations, the integrated circuit device 904 may perform signal processing on output sensed from the electromechanical pressure sensor 908. In some implementations, the integrated circuit 904 may be an application-specific integrated circuit (ASIC). In the example of FIGS. 9A and 9B, the integrated circuit device 904 is flip-chip bonded to bond pads 927a on the glass substrate 906. In some other implementations, the integrated circuit device may be wire bonded to bond pads or fabricated directly on the surface of the glass substrate 906.

The glass substrate 906 is substantially planar, having two major substantially parallel surfaces, an interior surface 926a and an exterior surface 926b. Through-glass vias 922 provide conductive pathways between portions of the interior surface 926a and the exterior surface 926b through the glass substrate 906. Conductive traces 924 on the interior surface 926a connect the through-glass vias 922 to bond pads 927a, which may be used for connections to the integrated circuit device 904. Bond pads 927b on the exterior surface 926b can provide electrical connections to the through-glass vias 922. The bond pads 927b can provide connections for external electrical contact, for example, by soldering or wire bonding to a PCB. The electromechanical pressure sensor 908 and the integrated circuit device 904 may be electrically connected to one or more of the through-glass vias 922 directly or indirectly by the conductive traces 924 on the interior surface 926a of the glass substrate 906. In the example shown, conductive traces 928 connect the pressure device 908 to bond pads 929; the bond pads 929 may be used for connections to the integrated circuit device 904.

In the examples of FIGS. 9A and 9B and the other Figures, through-glass vias 922 are cylindrically-shaped metal rods encased by glass substrate 906. Other types of through-glass vias can be used according to the desired implementation, including thin-film open or filled vias and plated open or filled vias. Further description of glass substrates and electrically conductive vias through glass substrates may be found in U.S. patent application Ser. No. 13/048,768, entitled “Thin Film Through-Glass Via and Methods for Forming Same” and filed Mar. 15, 2011, and in U.S. patent application Ser. No. 13/221,677, filed Aug. 30, 2011, and entitled “Die-Cut Through-Glass Via and Methods for Forming Same,” both of which are incorporated by reference herein.

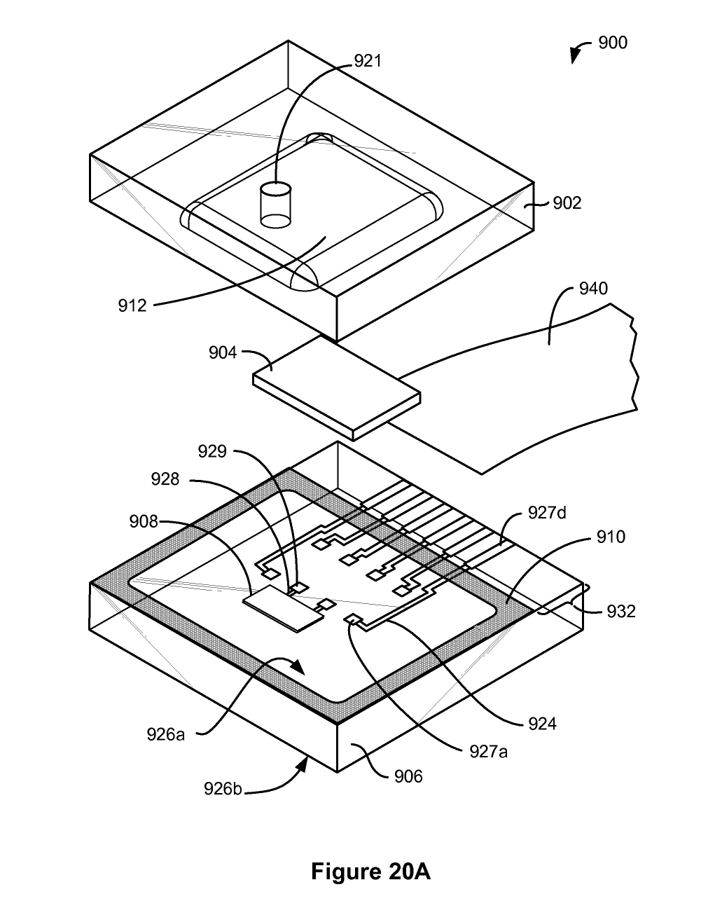

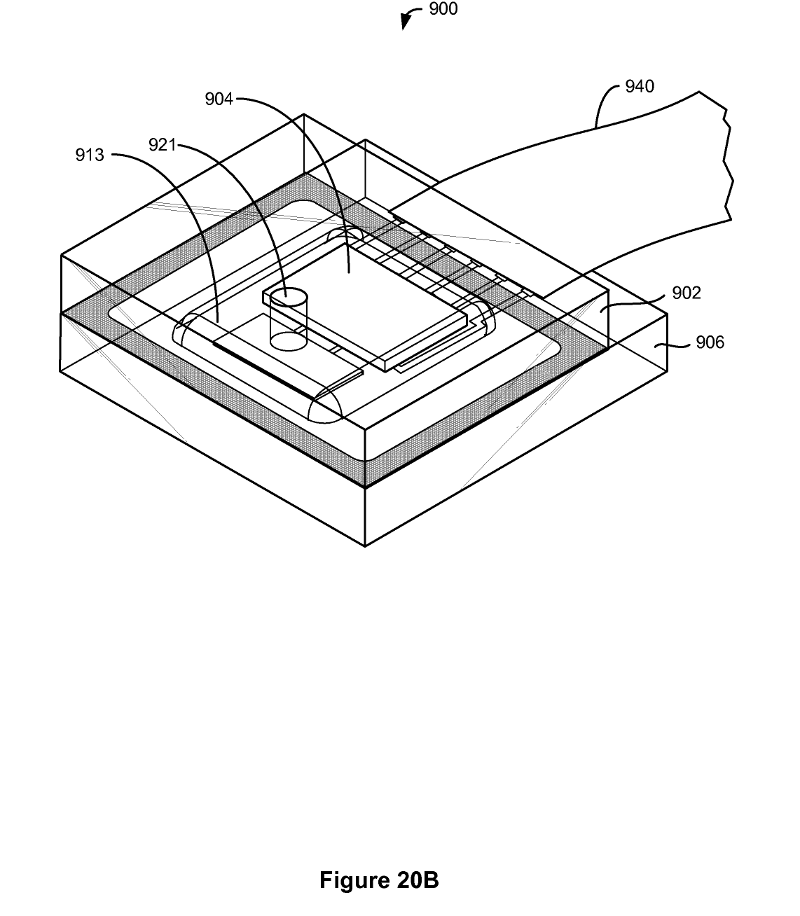

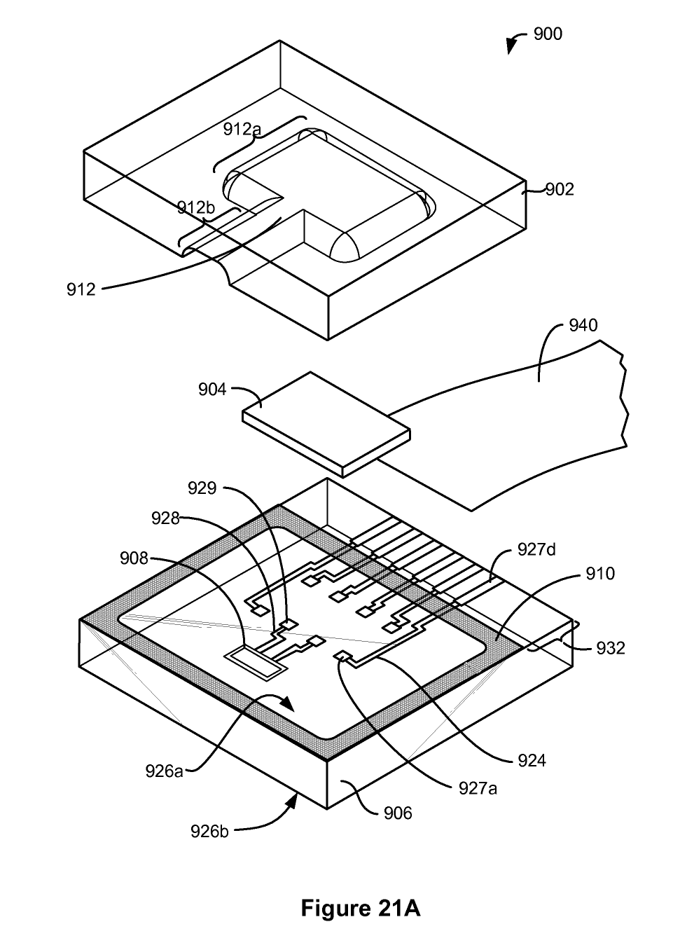

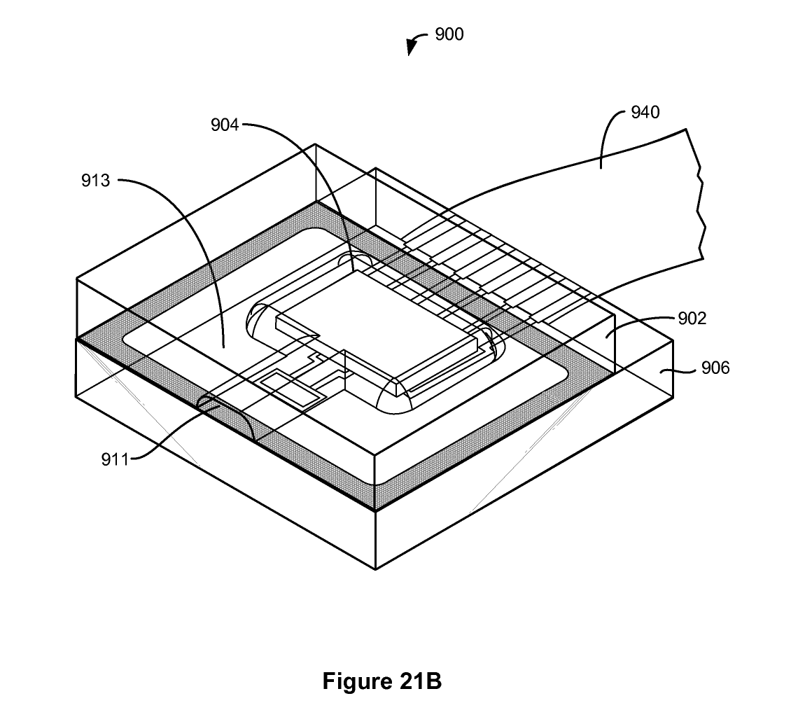

The arrangement of through-glass vias, traces, and bond pads associated with the glass substrate depicted in FIGS. 9A and 9B is an example of one possible arrangement; the particular arrangement used can vary according to the desired implementation. Moreover, a glass substrate and/or cover glass can include other electrical components instead of or in addition to through-glass vias, traces and bond pads. For example, in some implementations, a glass substrate can includes traces extending along a side surface of the glass substrate or cover glass to provide a conductive pathway from an interior surface of the glass substrate or cover glass to an exterior surface of the glass substrate or cover glass. These traces can be used instead of or in addition to through-glass vias to provide an electrical connection from the interior of the glass-encapsulated pressure sensor to its exterior. In another example, described further below with respect to FIGS. 20A-21B, bond pads on an exterior surface of a glass substrate can provide a connection point for flex tape. Further, in some implementations, a cover glass may include bond pads, traces, through-glass vias or other conductive pathways, in addition to or instead of components on or through a glass substrate.

In some implementations, at least a portion of the conductive traces 924 and 928 on the interior surface 926a may be passivated. For example, a portion of the conductive traces 924 and 928 that are exposed to the outside environment may be passivated with a passivation layer, such as a coating of an oxide or a nitride. A passivation layer may prevent the conductive traces 924 and 928 from becoming oxidized and possibly causing failure of the glass-encapsulated pressure sensor 900. The passivation layer may be deposited with a chemical vapor deposition (CVD) process or a physical vapor deposition (PVD) process, or other appropriate technique. Further, other exposed metal surfaces of the glass-encapsulated pressure sensor 900 also may be passivated.

The electromechanical pressure sensor 908 may be formed on or attached to the interior surface 926a of glass substrate 906. The electromechanical pressure sensor 908 depicted in the example of FIGS. 9A and 9B includes a substantially rectangular membrane 908a that deforms in response to pressure applied through port 911, generating an electrical signal that is sent to the integrated circuit device 904. The integrated circuit device 904 may amplify and digitize the signal from the electromechanical pressure sensor 908, in some implementations. In some implementations, the glass substrate 906 includes an etched recess (not shown) underlying the membrane 908a, such that a reference cavity is formed by the etched recess and the membrane 908a. The reference cavity can be vacuum sealed in some implementations. In some implementations, multiple pressure sensors may be formed on or attached to the interior surface 926a of glass substrate 906.

The joining ring 910 bonds the cover glass 902 to the glass substrate 906. The joining ring may be shaped in any appropriate manner and can be shaped and sized to correspond to the cover glass and the glass substrate to be joined. In the example shown in FIGS. 9A and 9B, the joining ring 910 surrounds the through-glass vias 922, the conductive traces 924 and 928, and the bond pads 927a and 929. In some other implementations, the joining ring can overlay some of the topside traces and/or some of the through-glass vias.

The joining ring 910 is an epoxy and can be any appropriate epoxy including UV curable epoxy or a heat-curable epoxy. In some other implementations, the joining ring may be or include any number of different bonding materials. Bonding materials including adhesives including epoxies. In some implementations, the joining ring may be a glass frit bond ring. In still other implementations, the joining ring may be a metal bond ring.

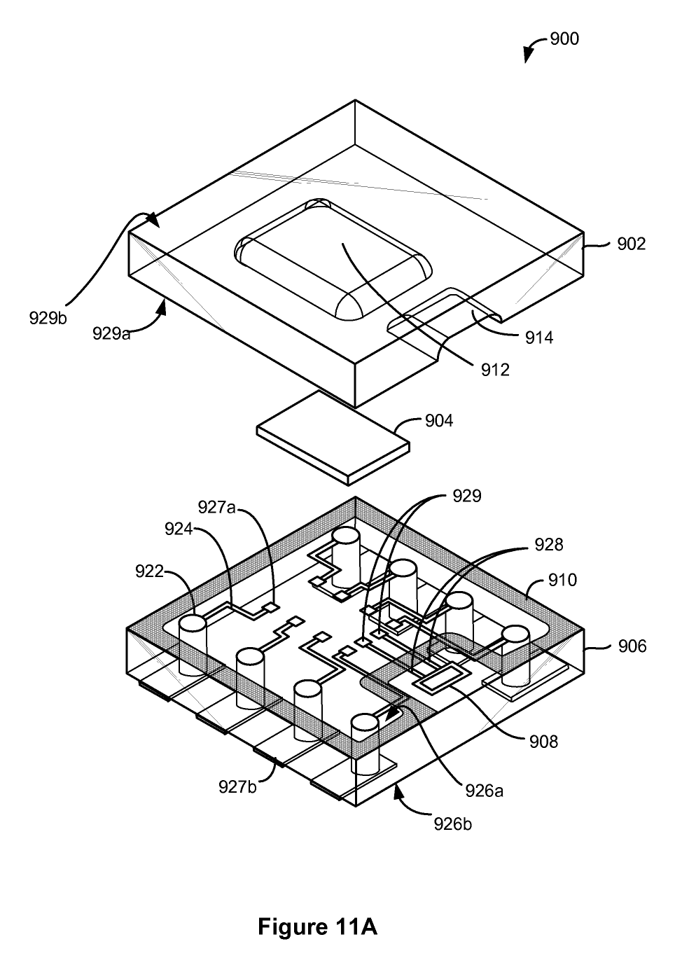

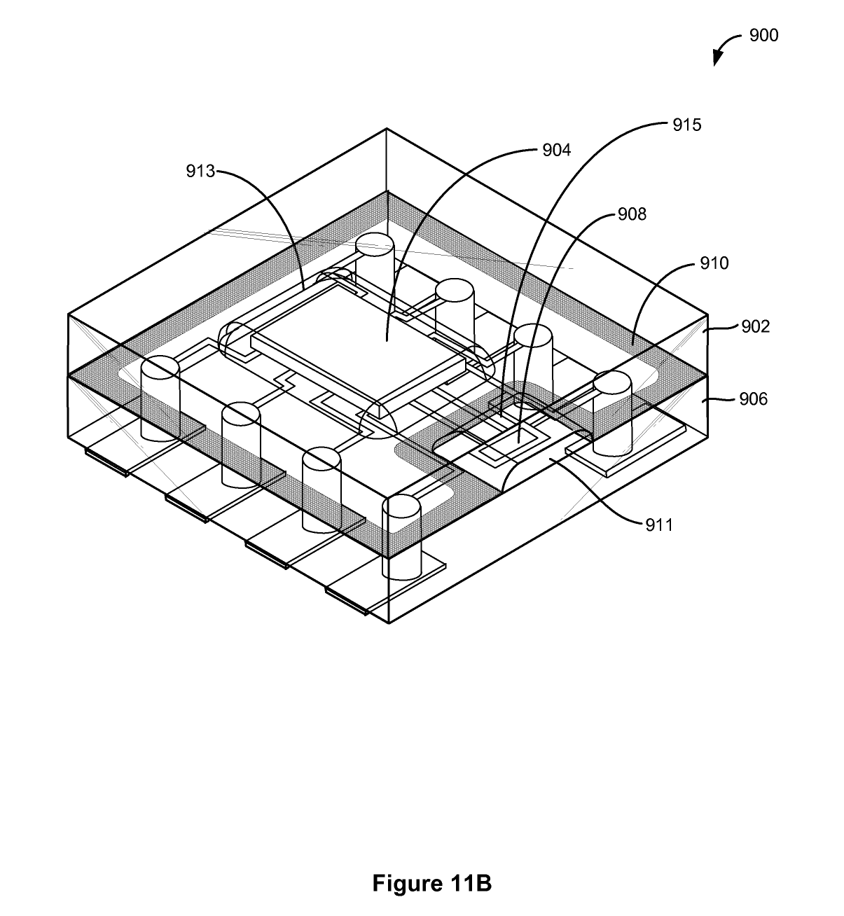

Although the joining ring 910 is depicted as being on interior surface 926a of glass substrate 906 in the exploded view of the glass-encapsulated pressure sensor of FIG. 9A, an epoxy or other bonding material can be dispensed on either or both of a glass substrate and a cover glass prior to joining the glass substrate and cover glass. The term joining ring may be used to refer to a ring of sealing material formed on a cover glass or glass substrate prior to joining, as well as a ring of sealing material disposed between a cover glass and glass substrate after joining A joining ring can wholly or partially surround one or more of components of a glass-encapsulated pressure sensor including one or more devices, recesses, or components of a conductive pathway. A joining ring can be shaped in any appropriate manner with example shapes including circles, ovals, rectangles, parallelograms and combinations thereof as well as irregular shapes. A joining ring can be continuous or can include breaks or other discontinuities according to the desired implementation. The joining ring can form a substantially hermetic seal or a non-hermetic seal according to the desired implementation. Examples of different joining ring configurations are discussed further below with reference to FIGS. 11A-21B.

In some implementations, an electrical connection from a pressure sensor to an exterior of the glass-encapsulated pressure sensor can include one or more conductive pathways on or through a cover glass. FIGS. 10A and 10B show examples of varying views of a glass-encapsulated pressure sensor including through-glass vias in a cover glass. FIG. 10A shows an example of an exploded view diagram of the glass-encapsulated pressure sensor. FIG. 10B shows an example of a simplified isometric view of the glass-encapsulated pressure sensor shown in FIG. 10A. For clarity, some components shown in FIG. 10A are not shown in FIG. 10B.

The glass-encapsulated pressure sensor 900 shown in FIGS. 10A and 10B includes a cover glass 902, an integrated circuit device 904, a glass substrate 906, an electromechanical pressure sensor 908, and a joining ring 910. For illustrative purposes, FIGS. 10A and 10B depict the glass-encapsulated pressure sensor 900 with the cover glass 902 on bottom and the glass substrate 906 on top. As in the example depicted in FIG. 9A, the cover glass 902 includes an interior surface 929a, an exterior surface 929b, and a single recess 912 such that when the cover glass 902 is bonded to the glass substrate 906, a cavity 913 is formed that accommodates the integrated circuit device 904 and the electromechanical pressure sensor 908. The recess 912 extends to a side of the cover glass 902 such that when the cover glass 902 is bonded to the glass substrate 906, a side port 911 is formed, as shown in the example of FIG. 10B. The side port 911 allows fluid access to the electromechanical pressure sensor 908. The cover glass 902 also includes through-glass vias 922, which extend from the interior surface 929a to the exterior surface 929b, as well as bond pads 927b on the exterior surface 929b. The through-glass vias 922 provide an electrical connection from the interior to the exterior of the glass-encapsulated pressure sensor 900. The bond pads 927b can provide connections for external electrical contact, for example, by soldering or wire bonding to a PCB.

The glass substrate 906 has two major substantially parallel surfaces, an interior surface 926a and an exterior surface 926b. Bond pads 927c on the interior surface 926a provide a point of connection for the through-glass vias 922 in the cover glass 902. Conductive traces 924 on the interior surface 926a connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. Accordingly, the conductive traces 924 and 928, the bond pads 927a, 927b, 927c and 929, and the through-glass vias 922 provide an electrical connection from the pressure sensor 908 to the exterior surface 929b of the cover glass 902. The cover glass 902 is joined to glass substrate by the joining ring 910 and metal solder that connects the through-glass vias 922 in the cover glass 902 to the bond pads 927c on the glass substrate 906. Joining ring materials are described above with respect to FIGS. 9A and 9B.

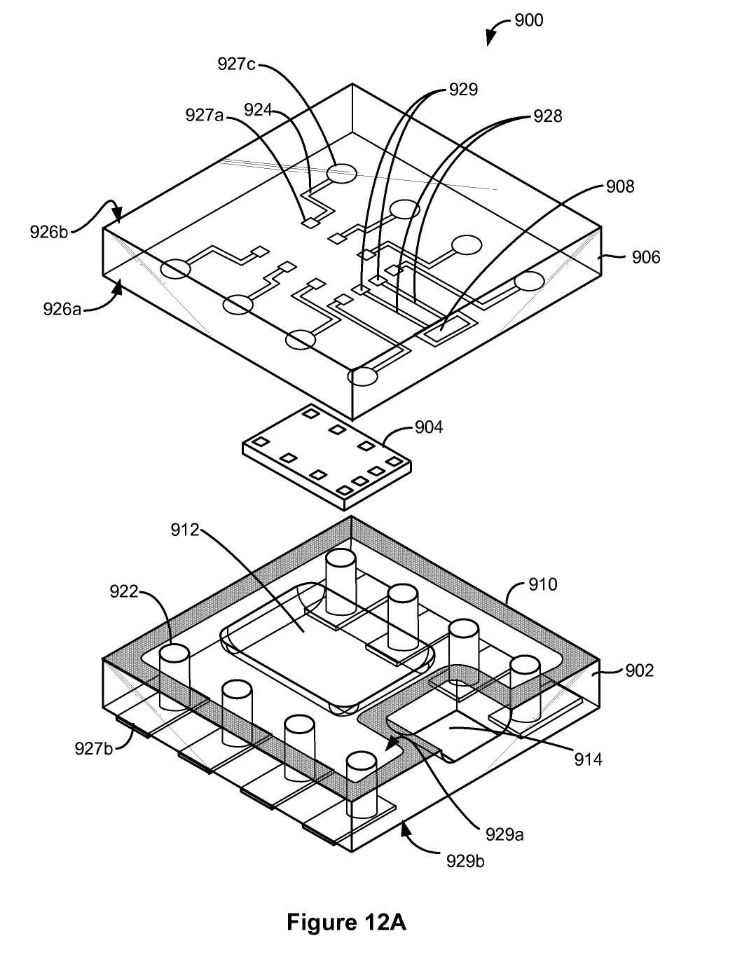

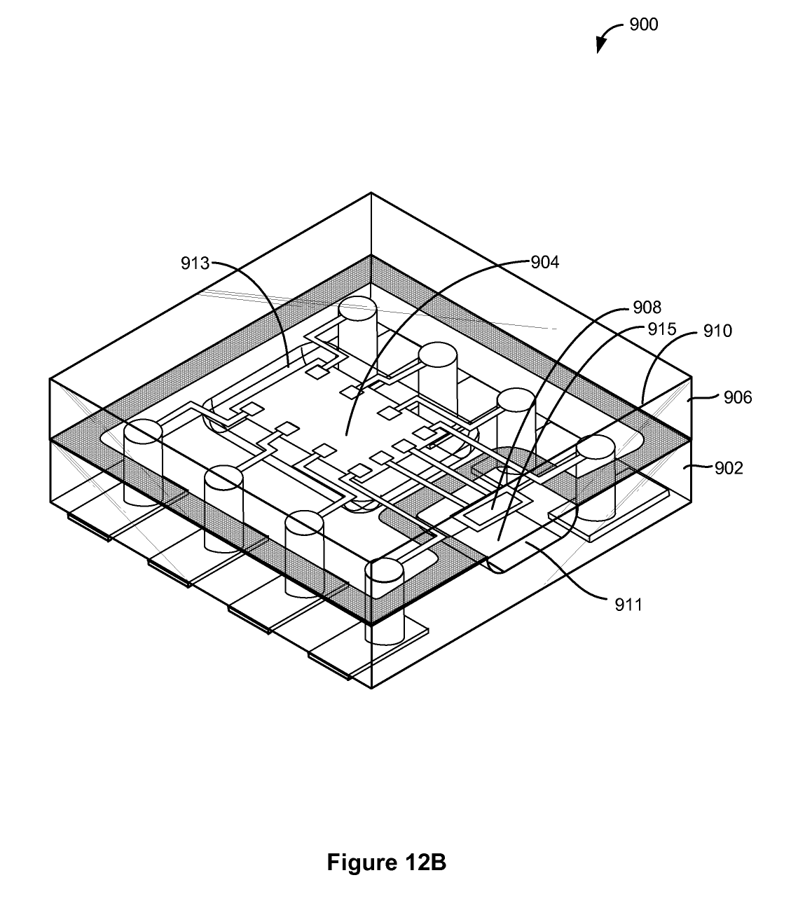

In some implementations, a glass-encapsulated pressure sensor may include multiple cavities. FIGS. 11A-12B show examples of varying views of a glass-encapsulated pressure sensor including multiple cavities. FIG. 11A shows an example of an exploded view diagram of a glass-encapsulated pressure sensor. FIG. 11B shows an example of a simplified isometric view of the glass-encapsulated pressure sensor shown in FIG. 11A. For clarity, some components shown in FIG. 11A are not shown in FIG. 11B. The glass-encapsulated pressure sensor 900 shown in FIGS. 11A and 11B includes a cover glass 902, an integrated circuit device 904, a glass substrate 906, an electromechanical pressure sensor 908, and a joining ring 910.

The cover glass 902 includes an interior surface 929a and an exterior surface 929b as well as two recesses, recess 912 and recess 914, in the interior surface 929a. When the cover glass 902 is bonded to the glass substrate 906, a cavity 913 is formed by the recess 912 and a cavity 915 is formed by the recess 914 as depicted in the example of FIG. 11B. The cavity 913 accommodates the integrated circuit device 904 and the cavity 915 accommodates the electromechanical pressure sensor 908. A portion of the recess 914 of the cover glass 902 is at a side of the cover glass 902. When the cover glass 902 is bonded to the glass substrate 906, a side port 911 is formed. The side port 911 allows fluid access to the electromechanical pressure sensor 908.

The depth and width of recess 914 determine the dimensions of side port 911. The dimensions of the side port 911 are sufficient to allow fluid access to and equilibration at pressure sensor 908. When the cover glass 902 is bonded to the glass substrate 906, the side port 911 may be about 2 to 300 microns high in some implementations. The port width may be about 5 microns to one-half the width of the cover glass in some implementations.

The joining ring 910 forms a continuous ring around the integrated circuit device 904. When the cover glass 902 is attached to the glass substrate 906 as depicted in the example of FIG. 11B, the joining ring 910 physically isolates the integrated circuit device 904 from the electromechanical pressure sensor 908 and from the side port 911. This may serve to protect the integrated circuit device 904 from the environment.

The glass substrate 906 includes two substantially parallel surfaces, interior surface 926a and exterior surface 926b. The pressure sensor 908 can be fabricated or otherwise disposed on the interior surface 926a, with the integrated circuit device 904 attached to the interior surface 926a by flip-chip attachment to bond pads 927a and 929. Conductive traces 928 connect the pressure sensor 908 to the integrated circuit device 908, and conductive traces 924 connect the integrated circuit device 904 to through-glass vias 922. The through-glass vias 922 provide an electrical connection to bond pads 927b on the exterior surface 926b of the glass substrate 906.

The conductive traces 928, which electrically connect the integrated circuit device 904 to the electromechanical pressure sensor 908, traverse the joining ring 910 in the examples of FIGS. 11A and 11B. The conductive traces 928 can go under, above or through the joining ring 910. The joining ring 910 in the example depicted in FIGS. 11A and 11B is an epoxy, though in other implementations it may include any number of different bonding materials as described above. In implementations in which the joining ring 910 is a metal bond ring, the conductive traces 928 may be electrically insulated by a dielectric layer, such an oxide or a nitride, to prevent shorting through the joining ring 910. Any traces or other metal components that cross a metal bond ring can be similarly insulated.

In some implementations, the joining ring 910 may hermetically seal the integrated circuit device 904. A hermetic seal is a seal that does not permit the flow of gasses. Thus, when the integrated circuit device 904 is hermetically sealed by the joining ring 910, the integrated circuit device is not exposed to gasses in the environment. In some implementations, a metal bond ring may be used to form a hermetic seal. In other implementations, the joining ring 910 may form a non-hermetic seal or a partially hermetic seal. In some implementations, the width of the joining ring is between about 50 and 200 microns. In some implementations in which solder or eutectic joining is performed, a width of about 50 to 100 microns can be sufficient to provide a hermetic seal. In some implementations, the width can vary depending on the method by which joining ring solder material is formed. For seals having widths of about 200 microns or greater, screen printing can be used. For narrower seals, e.g., 50 to 100 microns, plating or thin-film depositions can be used. In some implementations in which an epoxy or polymer adhesive is used, the width of the joining ring can be larger, such as around 200 microns or larger, to provide a hermetic seal according to the desired implementation. If a non-hermetic or partially hermetic seal is desired, the width of a joining ring can be smaller in some implementations.

FIGS. 12A and 12B show another example of varying views of a glass-encapsulated pressure sensor including multiple cavities. FIG. 12A shows an example of an exploded view diagram of the glass-encapsulated pressure sensor. FIG. 12B shows an example of a simplified isometric view of the glass-encapsulated pressure sensor shown in FIG. 12A. For clarity, some components shown in FIG. 12A are not shown in FIG. 12B. The glass-encapsulated pressure sensor 900 shown in FIGS. 12A and 12B includes a cover glass 902, an integrated circuit device 904, a glass substrate 906, an electromechanical pressure sensor 908, and a joining ring 910. For illustrative purposes, FIGS. 12A and 12B depict the glass-encapsulated pressure sensor 900 with the cover glass 902 on bottom and the glass substrate 906 on top.

As in the example depicted in FIG. 11A, the cover glass 902 in FIG. 12A includes an interior surface 929a, an exterior surface 929b, with two recesses, recess 912 and recess 914, in the interior surface 929a. When the cover glass 902 is bonded to the glass substrate 906, a cavity 913 is formed by the recess 912 and a cavity 915 is formed by the recess 914 as depicted in the example of FIG. 12B. The cavity 913 accommodates the integrated circuit device 904 and the cavity 915 accommodates the electromechanical pressure sensor 908. A portion of the recess 914 of the cover glass 902 is at a side of the cover glass 902 such that when the cover glass 902 is bonded to the glass substrate 906, a side port 911 is formed. The side port 911 allows fluid access to the electromechanical pressure sensor 908.

The joining ring 910 forms a continuous ring around the integrated circuit device 904. When the cover glass 902 is attached to the glass substrate 906 as depicted in the example of FIG. 12B, the joining ring 910 physically isolates the integrated circuit device 904 from the electromechanical pressure sensor 908 and from the side port 911. This may serve to protect the integrated circuit device 904 from the environment.

The cover glass 902 also includes through-glass vias 922, which extend from the interior surface 929a to the exterior surface 929b, as well as bond pads 927b on the exterior surface 929b. The through-glass vias 922 provide an electrical connection from the interior to the exterior of the glass-encapsulated pressure sensor 900. The bond pads 927b can provide connections for external electrical contact, for example, by soldering or wire bonding to a PCB.

The glass substrate 906 is substantially planar, having two major substantially parallel surfaces, an interior surface 926a and an exterior surface 926b. Bond pads 927c on the interior surface 926a provide a point of connection for the through-glass vias 922 in the cover glass 902. Conductive traces 924 on the interior surface 926a can connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. Accordingly, the conductive traces 924 and 928, the bond pads 927a, 927b, 927c and 929, and the through-glass vias 922 provide an electrical connection between the pressure sensor 908 and the exterior surface 929b of the cover glass 902. The cover glass 902 is joined to the glass substrate 906 by the joining ring 910 as well as by metal solder that connects the through-glass vias 922 in the cover glass 902 to the bond pads 927c on the glass substrate 906.

The conductive traces 928, which traverse the joining ring 910, can go under, above or through the joining ring 910. The joining ring 910 in this example is an epoxy, though in other implementations it may include any number of different bonding materials, as described above. In implementations in which the joining ring 910 is a metal bond ring, the conductive traces 928 may be electrically insulated by a dielectric layer, such an oxide or a nitride, to prevent shorting through the joining ring 910.

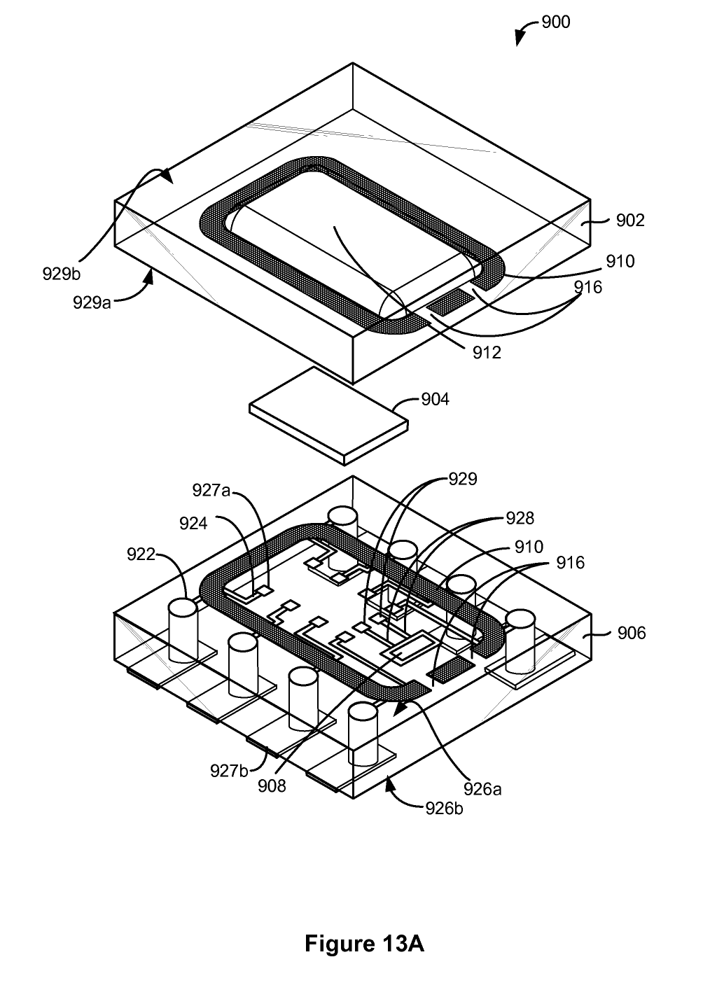

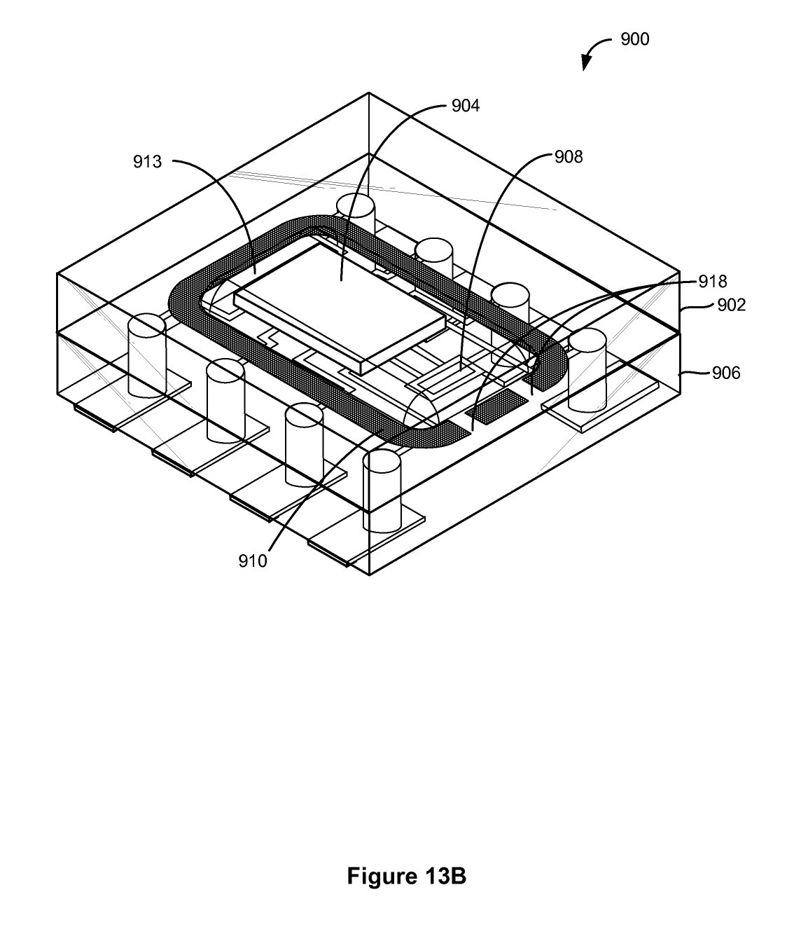

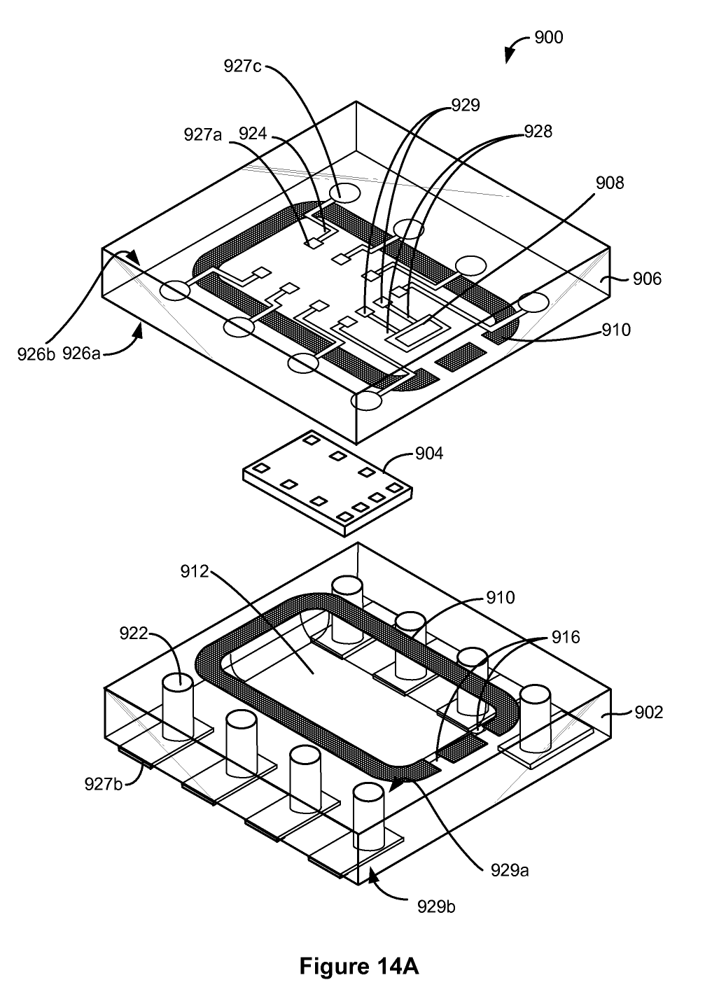

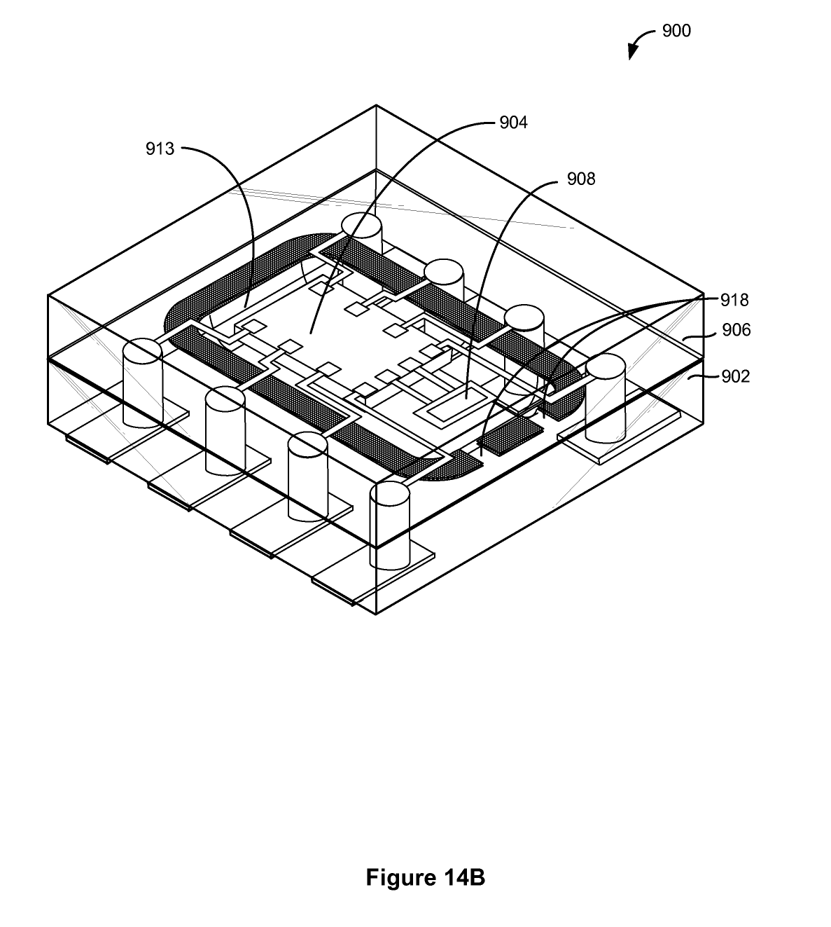

As described above, in some implementations, a side port allowing fluid access to an electromechanical pressure sensor is defined at least in part by a recess in a cover glass. In some implementations, a side port is at least partially defined by one or more channels in an interface between a cover glass and a glass substrate. For example, in some implementations a side port can be defined by one or more channels in a joining ring. A side port including one or more channels in a joining ring may or may not include a recess in a cover glass according to the desired implementation. Examples of glass-encapsulated pressure sensors including channels through a joining ring are described below with reference to FIGS. 13A-14B.

As indicated above, in some implementations, a glass-encapsulated pressure sensor can include a metal bond ring. A metal bond ring can be used instead of or in addition to an epoxy, for example, to bond a cover glass and a glass substrate together. FIGS. 13A-14B show examples of varying views of glass-encapsulated pressure sensors including a metal bond ring. FIG. 13A shows an example of an exploded view diagram of the glass-encapsulated pressure sensor including a metal bond ring. FIG. 13B shows an example of a simplified isometric view of the glass-encapsulated pressure sensor shown in FIG. 13A. For clarity, some components shown in FIG. 13A are not shown in FIG. 13B.

The glass-encapsulated pressure sensor 900 shown in FIGS. 13A and 13B includes a cover glass 902, an integrated circuit device 904, a glass substrate 906, an electromechanical pressure sensor 908, and a joining ring 910. The cover glass 902 in the example of FIGS. 13A and 13B is substantially planar and includes an interior surface 929a and an exterior surface 929b. A recess 912 is formed in the interior surface 929a. When the cover glass 902 is bonded to the glass substrate 906, a cavity 913 is formed by the recess 912 as shown in FIG. 13B. The cavity 913 accommodates the integrated circuit device 904 and the electromechanical pressure sensor 908.

The joining ring 910 forms a discontinuous ring around the integrated circuit device 904, the pressure sensor 908 and a perimeter of the cavity 913. When the cover glass 902 is bonded to the glass substrate 906, discontinuities 916 (shown in FIG. 13A) form channels 918 (shown in FIG. 13B) that can serve as a pressure port to allow pressure equilibration.

In the example of FIGS. 13A and 13B, the joining ring 910 is a metal bond ring. A metal bond ring may include a solderable metallurgy, a eutectic metallurgy, a solder paste, or the like. Examples of solderable metallurgies include nickel/gold (Ni/Au), nickel/palladium (Ni/Pd), nickel/palladium/gold (Ni/Pd/Au), copper (Cu), and gold (Au). Eutectic metal bonding can involves forming a eutectic alloy layer between a cover glass and a glass substrate. Examples of eutectic alloys that may be used include indium/bismuth (InBi), copper/tin (CuSn), and gold/tin (AuSn). Melting temperatures of these eutectic alloys are about 150° C. for the InBi eutectic alloy, about 225° C. for the CuSn eutectic alloy, and about 305° C. for the AuSn eutectic alloy.

In some implementations, a metal bond ring such as joining ring 910 in the example of FIGS. 13A and 13B can be formed by plating or vapor deposition of metal rings on the cover glass 902 and the glass substrate 906, and forming a solder bond between these metal rings. Any other appropriate method of forming a metal bond ring also can be used. In some other implementations a discontinuous joining ring, such as joining ring 910 in FIGS. 13A and 13B, can be formed from a non-metal bonding material, such as an epoxy or glass frit material.

In the example of FIG. 13B, the thickness of joining ring 910 determines the height of channels 918. In some implementations, the joining ring thickness, and thus the channel height, can be between 0.2 and 50 microns, for example, between 0.5 and 10 microns. The width of the discontinuities 916 determines the width of the channels 918. In some implementation, the width of the discontinuities, and thus the channel width, can be between about 5 and 100 microns, for example, between about 10 and 20 microns. In some implementations, the size of the channels 918 or other side port is constrained by the particular fabrication process used rather than operating characteristics of the pressure sensor 908, if the fluid to be measured can equilibrate quickly through small area ports. The width of the joining ring 910 can be between about 5 and 100 microns, for example.

In the example of FIGS. 13A and 13B, conductive traces 924 and 928 and bond pads 927a and 929 are formed on an interior surface 926a of the glass substrate 906. The conductive traces 924, which connect the bond pads 927a to through-glass vias 922, cross under or through the joining ring 910. The conductive traces 924 can be electrically insulated from the joining ring 910. The conductive traces 924 can be coated with a dielectric material, such as an oxide or a nitride, to provide electrical insulation.

In addition to joining ring 910, an interior surface 926a of glass substrate 906 also has the pressure sensor 908, conductive traces 924 and 928 and bond pads 927b and 929 disposed thereon. The integrated circuit device 904 can be attached to the bond pads 927a and 929. Through-glass vias 922 provide a connection through the glass substrate 906. These components and other examples of electrical connections between any of an integrated circuit device, a pressure sensor, and connections for external electrical contact according to the desired implementation are described further above with respect to FIGS. 9A and 9B.

FIGS. 14A and 14B show another example of varying views of a glass-encapsulated pressure sensor including a metal bond ring. FIG. 14A shows an example of an exploded view diagram of the glass-encapsulated pressure sensor. FIG. 14B shows an example of a simplified isometric view of the glass-encapsulated pressure sensor shown in FIG. 14A. For clarity, some components shown in FIG. 14A are not shown in FIG. 14B. The glass-encapsulated pressure sensor 900 shown in FIGS. 14A and 14B includes a cover glass 902, an integrated circuit device 904, a glass substrate 906, an electromechanical pressure sensor 908, and a joining ring 910. For illustrative purposes, FIGS. 14A and 14B depict the glass-encapsulated pressure sensor 900 with the cover glass 902 on bottom and the glass substrate 906 on top.

The cover glass 902 in the example of FIGS. 14A and 14B is substantially planar and includes an interior surface 929a and an exterior surface 929b. A recess 912 is formed in the interior surface 929b. When the cover glass 902 is bonded to the glass substrate 906, a cavity 913 is formed by the recess 912 as shown in FIG. 14B. The cavity 913 accommodates the integrated circuit device 904 and the electromechanical pressure sensor 908.

The joining ring 910 forms a discontinuous ring around the integrated circuit device 904, the pressure sensor 908 and a perimeter of the cavity 913. When the cover glass 902 is bonded to the glass substrate 906, discontinuities 916 form channels 918 that can serve as a pressure port to allow pressure ingress and egress. Examples of materials for a metal bond ring 910 are described above with respect to FIGS. 13A and 13B. Examples of channel dimensions are also described above with respect to FIGS. 13A and 13B.

The cover glass 902 also includes through-glass vias 922, which extend from the interior surface 929a to the exterior surface 929b, as well as bond pads 927b on the exterior surface 929b. The through-glass vias 922 can provide an electrical connection from the interior to the exterior of the glass-encapsulated pressure sensor 900. The bond pads 927b can provide connections for external electrical contact, for example, by soldering or wire bonding to a PCB.

The glass substrate 906 is substantially planar, having two major substantially parallel surfaces, an interior surface 926a and an exterior surface 926b. Bond pads 927c on the interior surface 926a provide a point of connection for through-glass vias 922 in the cover glass 902. Conductive traces 924 on the interior surface 926a can connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. Accordingly, the conductive traces 924 and 928, the bond pads 927a, 927b, 927c and 929, and the through-glass vias 922 provide an electrical connection from the pressure sensor 908 to the exterior surface 929b of cover glass 902. The cover glass 902 is joined to glass substrate by the joining ring 910 and metal solder that connects the through-glass vias 922 in the cover glass 902 to the bond pads 927c on the glass substrate 906.

In the example of FIGS. 14A and 14B, the conductive traces 924, which connect the bond pads 927a to the through-glass vias 922, cross under or through the joining ring 910. The conductive traces 924 can be electrically insulated from the joining ring 910. The conductive traces 924 can be coated with a dielectric material, such as an oxide or a nitride, to provide electrical insulation.

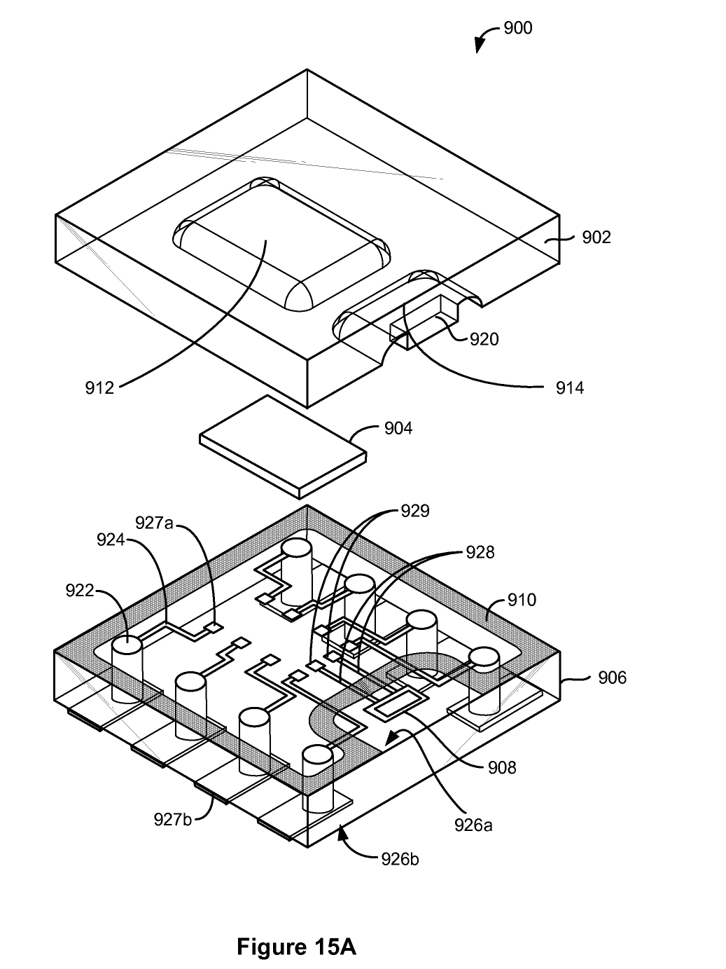

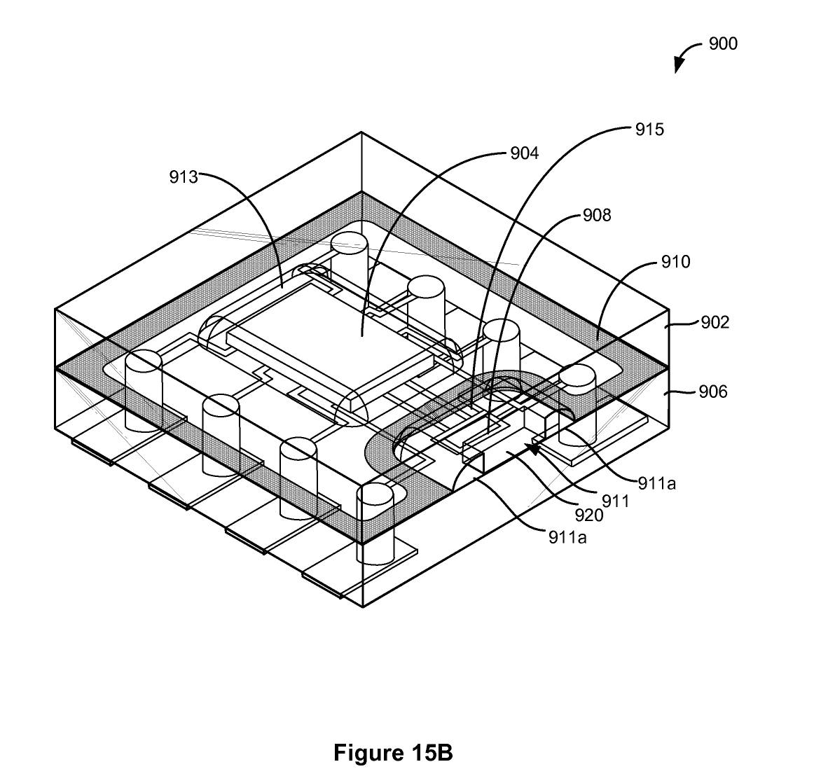

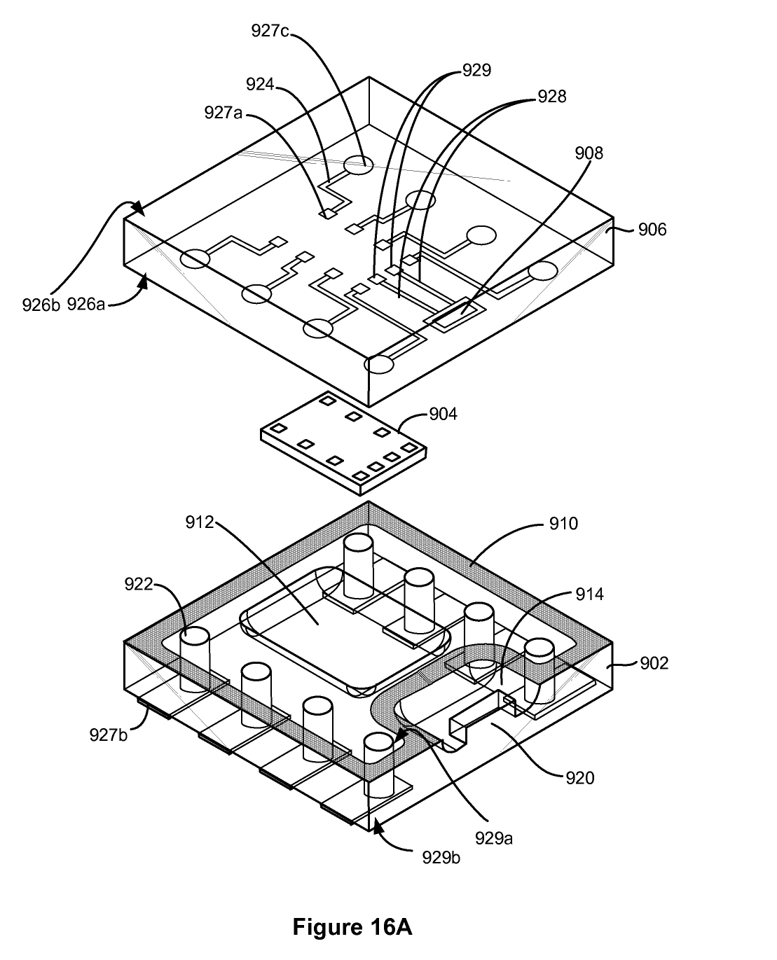

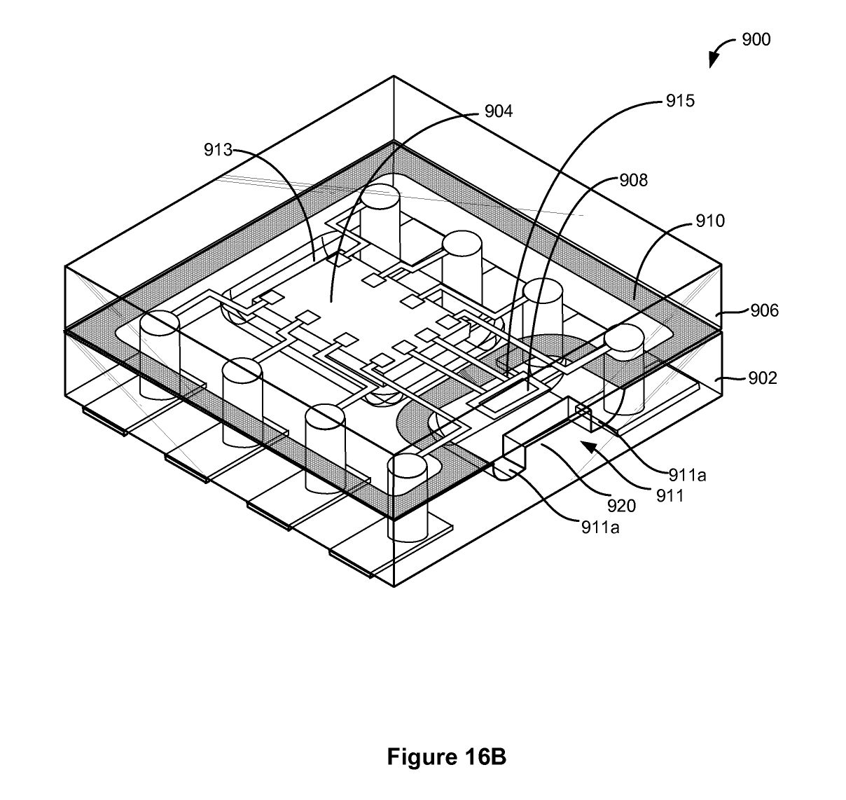

In some implementations, a side port can include one or more features configured to protect a pressure sensor during fabrication of a glass-encapsulated pressure sensor and/or during use. For example, a portion of joining ring 910 in FIGS. 13B and 14B between channels 918 partially obstructs pressure sensor 908. Further examples are described below with reference to FIGS. 15A-16B, which show examples of varying views of glass-encapsulated pressure sensors including a sensor-protecting feature.

The glass-encapsulated pressure sensor 900 shown in FIGS. 15A and 15B includes a cover glass 902, an integrated circuit device 904, a glass substrate 906, an electromechanical pressure sensor 908, and a joining ring 910. The cover glass 902 includes two recesses, recess 912 and recess 914 as shown in the example of FIG. 15A. When the cover glass 902 is bonded to the glass substrate 906, a cavity 913 is formed by the recess 912 and a cavity 915 is formed by the recess 914 as depicted in the example of FIG. 15B. The cavity 913 accommodates the integrated circuit device 904 and the cavity 915 accommodates the electromechanical pressure sensor 908. A portion of the recess 914 of the cover glass 902 is at an edge of the cover glass. When the cover glass 902 is bonded to the glass substrate 906, a side port 911 is formed. The side port 911 allows fluid access to the electromechanical pressure sensor 908.

A fence 920 is disposed in the recess 914 at the edge of cover glass 902. When the cover glass 902 is bonded to the glass substrate 906, the fence 920 sits between the pressure sensor 908 and the edge of the cover glass 902. The fence 920 can provide some protection for the pressure sensor 908 from dicing fluid, dirt, debris and other environmental conditions during fabrication or use.

The side port 911 includes the fence 920 and two channels 911a that provide fluid access to pressure sensor 908. The channels 911a of the side port 911 may be about 2 to 300 microns high in some implementations. The width of each channel 911a of the side port 911 may be between about 5 microns and one-fourth the width of the cover glass in some implementations.

The joining ring 910 forms a continuous ring around the integrated circuit device 904. When the cover glass 902 is attached to the glass substrate 906 as depicted in the example of FIG. 15B, the joining ring 910 surrounds the cavity 913, physically isolating the integrated circuit device 904 from the electromechanical pressure sensor 908 and from the side port 911. This may serve to protect the integrated circuit device 904 from the environment.

The glass substrate 906 includes an interior surface 926a and an exterior surface 926b. Conductive traces 924 on the interior surface 926a connect through-glass vias 922 to bond pads 927a, which may be used for connections to the integrated circuit device 904. Through-glass vias 922 provide a point of connection to the bond pads 927b on the exterior surface 926b. Conductive traces 928 connect the pressure sensor 908 to bond pads 929; the bond pads 929 may be used for connections to the integrated circuit device 904. Accordingly, the conductive traces 924 and 928, the bond pads 927a, 927b, and 929, and the through-glass vias 922 provide an electrical connection from the pressure sensor 908 to the exterior surface 926b of the glass substrate 906. The cover glass 902 is joined to glass substrate by joining ring 910.

The conductive traces 928 electrically connecting the integrated circuit device 904 to the electromechanical pressure sensor 908 traverse the joining ring 910 in the example of FIGS. 15A and 15B. The top side traces can go under, above or through the joining ring 910. The joining ring 910 in this example is an epoxy, though in some other implementations it may include any number of different bonding materials, as described above. In implementations in which the joining ring 910 is a metal bond ring, the topside traces 928 may be electrically insulated by a dielectric layer, such an oxide or a nitride, to prevent shorting through the joining ring 910.

In some implementations, the joining ring 910 may hermetically seal the integrated circuit device 904. Thus, when the integrated circuit device 904 is hermetically sealed by the joining ring 910, the integrated circuit device is not exposed to gasses in the environment. Hermetic seals are described above with respect to FIGS. 11A and 11B.

FIGS. 16A and 16B show another example of varying views of a glass-encapsulated pressure sensor including a sensor protecting feature. FIG. 16A shows an example of an exploded view diagram of the glass-encapsulated pressure sensor. FIG. 16B shows an example of a simplified isometric view of the glass-encapsulated pressure sensor shown in FIG. 16A. For clarity, some components shown in FIG. 16A are not shown in FIG. 16B. The glass-encapsulated pressure sensor 900 shown in FIGS. 16A and 16B includes a cover glass 902, an integrated circuit device 904, a glass substrate 906, an electromechanical pressure sensor 908, and a joining ring 910. For illustrative purposes, FIGS. 16A and 16B depict the glass-encapsulated pressure sensor 900 with the cover glass 902 on bottom and the glass substrate 906 on top.

The cover glass 902 includes two recesses, recess 912 and recess 914 as shown in the example of FIG. 16A. When the cover glass 902 is bonded to the glass substrate 906, a cavity 913 is formed by the recess 912 and a cavity 915 is formed by the recess 914 as depicted in the example of FIG. 16B. The cavity 913 accommodates the integrated circuit device 904 and the cavity 915 accommodates the electromechanical pressure sensor 908. A portion of the recess 914 of the cover glass 902 is at an edge of the cover glass 902. When the cover glass 902 is bonded to the glass substrate 906, a side port 911 is formed. The side port 911 allows fluid access to the electromechanical pressure sensor 908.

The recess 914 includes a fence 920 at the edge of cover glass 902. When the cover glass 902 is bonded to the glass substrate 906, the fence 920 sits between the pressure sensor 908 and the edge of the cover glass 902. The fence 920 can provide some protection for the pressure sensor 908 from dicing fluid, dirt, debris and other environmental conditions during fabrication or use. The side port 911 includes the fence 920 and two channels 911a that provide fluid access to pressure sensor 908. Channel dimensions are described above with respect to FIGS. 15A and 15B.

The joining ring 910 forms a continuous ring around the integrated circuit device 904. When the cover glass 902 is attached to the glass substrate 906 as depicted in the example of FIG. 16B, the joining ring 910 surrounds the integrated circuit device, physically isolating the integrated circuit device 904 from the electromechanical pressure sensor 908 and from the side port 911. This may serve to protect the integrated circuit device 904 from the environment.

The glass substrate 906 includes an interior surface 926a and an exterior surface 926b. Bond pads 927c on the interior surface 926a provide a point of connection for through-glass vias 922 in cover glass 902. Conductive traces 924 on the interior surface 926a connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. The cover glass 902 is joined to glass substrate by joining ring 910 and metal solder that connects the through-glass vias 922 in the cover glass 902 to the bond pads 927c on the glass substrate 906.

The conductive traces 928 electrically connecting the integrated circuit device 904 to the electromechanical pressure sensor 908 traverse the joining ring 910 in the example of FIG. 16B. The joining ring 910 in this example is an epoxy, though in other implementations it may include any number of different bonding materials, as described above. In implementations in which the joining ring 910 is a metal bond ring, the topside traces 928 may be electrically insulated by a dielectric layer, such an oxide or a nitride, to prevent shorting through the joining ring 910. In some implementations, the joining ring 910 may hermetically seal the integrated circuit device 904; a hermetic seal is a seal that does not permit the flow of gasses.

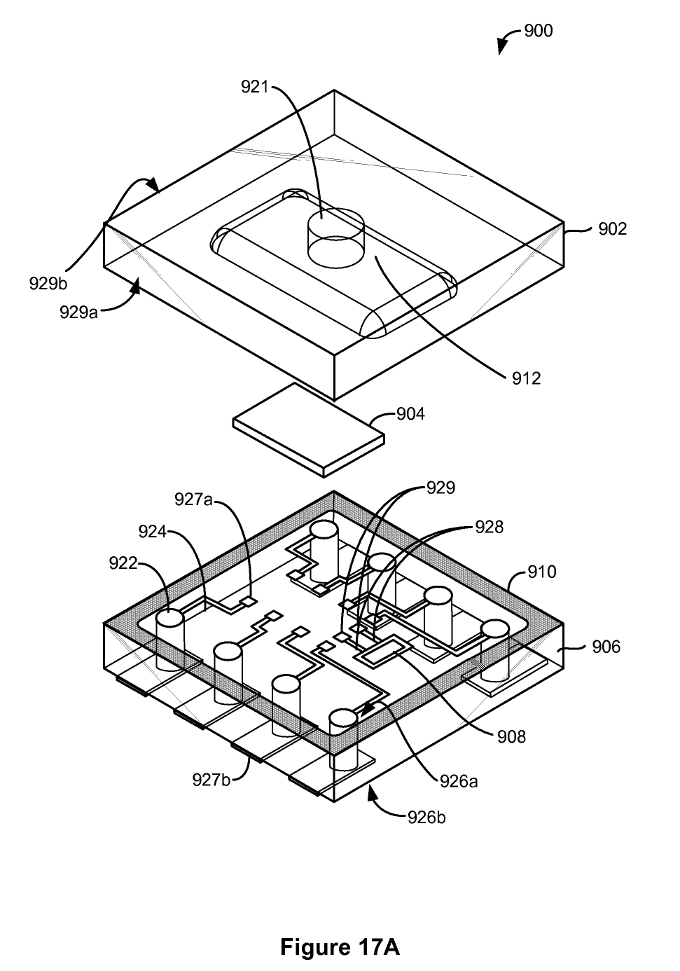

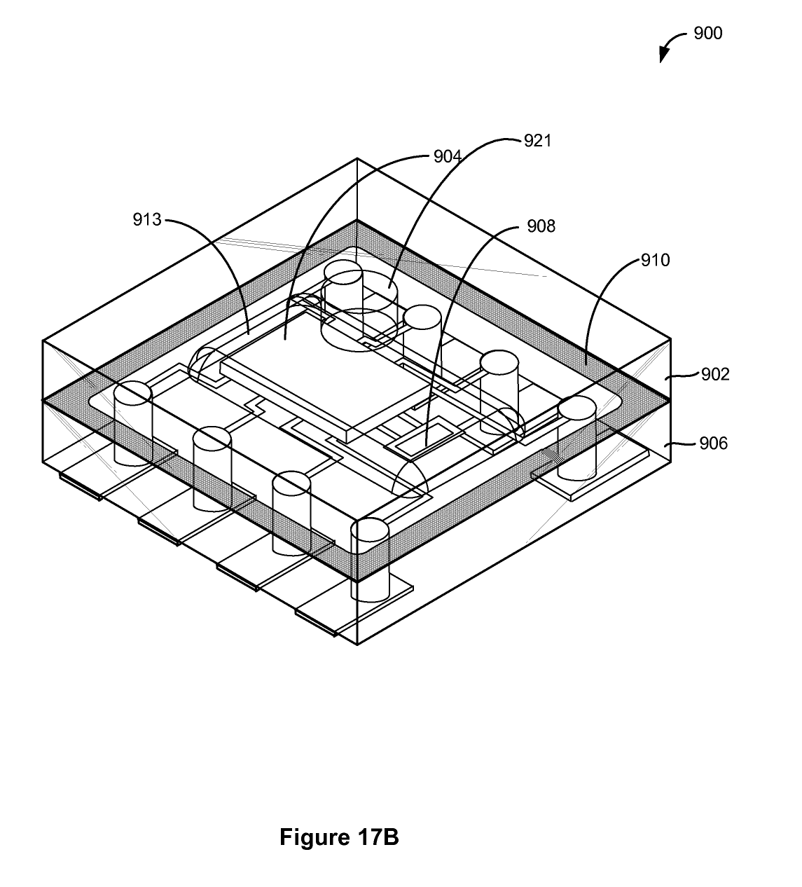

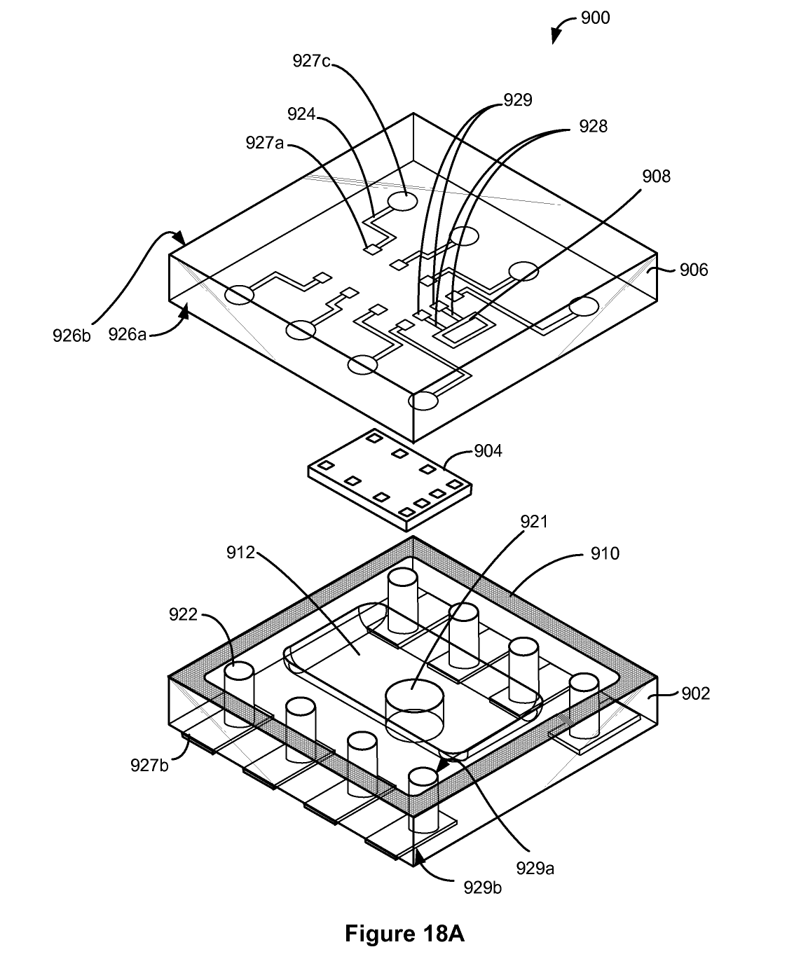

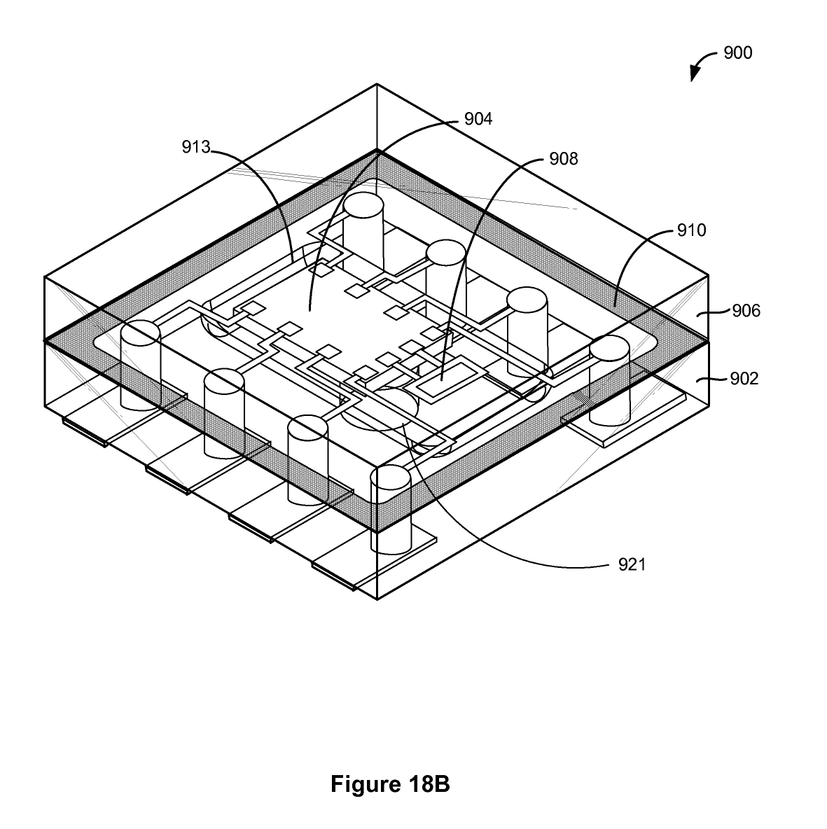

In some implementations, a port can extend through a cover glass or a glass substrate. FIGS. 17A-18B show examples of varying views of a glass-encapsulated pressure sensor including a port extending through a cover glass. FIG. 17A shows an example of an exploded view diagram of a glass-encapsulated pressure sensor. FIG. 17B shows an example of a simplified isometric view of the glass-encapsulated pressure sensor shown in FIG. 17A. For clarity, some components shown in FIG. 17A are not shown in FIG. 17B. The glass-encapsulated pressure sensor 900 shown in FIGS. 17A and 17B includes a cover glass 902, an integrated circuit device 904, a glass substrate 906, an electromechanical pressure sensor 908, and a joining ring 910.

The cover glass 902 includes an interior surface 929a, an exterior surface 929b, and a recess 912 in the interior surface 929a. When the cover glass 902 is bonded to the glass substrate 906, a cavity 913 is formed by the recess 912 as depicted in the example of FIG. 17B. The cavity 913 accommodates the integrated circuit device 904 and the electromechanical pressure sensor 908. The cover glass 902 also includes a topside port 921 that extends through the cover glass 902. The topside port 921 allows fluidic access to the pressure sensor 908. In the example of FIGS. 17A and 17B, the topside port 921 is centered in the cover glass 902, though in some other implementations, the topside port 921 can be offset from the center of the cover glass 902. For example, the topside port 921 can be directly over the pressure sensor 908. Also, in the example of FIGS. 17A and 17B, the topside port is connected to the recess 912; in some other implementations, the topside port 921 can extend from the exterior surface 929b to the interior surface 929a separated from the recess 912. The dimensions of the topside port 921 are sufficient to allow fluid access to and equilibration at pressure sensor 908. While the topside port 921 in the examples of FIGS. 17A and 17B has circular openings, it can be any appropriate shape including square-shaped, slot-shaped, etc. Examples of opening dimensions can be about 50 to 300 microns. The topside port 921 may be in a number of different configurations, including multiple holes and tapered holes, for example.

The glass substrate 906 includes interior surface 926a and exterior surface 926b, with through-glass vias 922 providing an electrical connection between these surfaces. The pressure sensor 908 can be fabricated on the interior surface 926a, with the integrated circuit device 904 attached to interior surface 926a, for example by flip-chip attachment to bond pads 927a and 929. Conductive traces 928 connect the pressure sensor 908 to integrated circuit device 904. Conductive traces 924 connect integrated circuit device 904 to through-glass vias 922. The through-glass vias 922 provide an electrical connection to bond pads 927b on the exterior surface 926b. The joining ring 910 extends around the periphery of the glass substrate 906, forming a continuous ring around the integrated circuit device 904, the pressure sensor 908, as well as to the conductive traces 924 and 928, the bond pads 927a and 929, and the through-glass vias 922.

FIGS. 18A-18B show another example of varying views of a glass-encapsulated pressure sensor including a port extending through a cover glass. FIG. 18A shows an example of an exploded view diagram of the glass-encapsulated pressure sensor. FIG. 18B shows an example of a simplified isometric view of the glass-encapsulated pressure sensor shown in FIG. 18A. For clarity, some components shown in FIG. 18A are not shown in FIG. 18B. The glass-encapsulated pressure sensor 900 shown in FIGS. 18A and 18B includes a cover glass 902, an integrated circuit device 904, a glass substrate 906, an electromechanical pressure sensor 908, and a joining ring 910. For illustrative purposes, FIGS. 18A and 18B depict the cover glass 902 on bottom and the glass substrate 906 on top.

The cover glass 902 includes an interior surface 929a and an exterior surface 929b. A recess 912 is formed in the interior surface 929a, as shown in the example of FIG. 18A. When the cover glass 902 is bonded to the glass substrate 906, a cavity 913 is formed by the recess 912 as shown in the example of FIG. 18B. The cavity 913 accommodates the integrated circuit device 904 and the electromechanical pressure sensor 908. Through-glass vias 922 extend through the cover glass 902, providing a connection between the components in the interior of the glass-encapsulated pressure sensor 900 and bond pads 927b on the exterior surface 929b of the cover glass 902.

The glass substrate 906 includes an interior surface 926a and an exterior surface 926b. Bond pads 927c on the interior surface 926a provide a point of connection for the through-glass vias 922 in the cover glass 902. Conductive traces 924 on the interior surface 926a connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. Accordingly, the conductive traces 924 and 928, the bond pads 927a, 927b, 927c and 929, and the through-glass vias 922 provide an electrical connection from the pressure sensor 908 to the exterior surface 929b of the cover glass 902. The cover glass 902 is joined to the glass substrate 906 by the joining ring 910 and metal solder that connects the through-glass vias 922 in the cover glass 902 to the bond pads 927c on the interior surface 926a of the glass substrate 906.

A topside port 921 extends through the cover glass 902. The topside port 921 allows fluid access to the pressure sensor 908. (The term “topside” is used for ports extending through a cover glass, with “bottomside” used for ports extending through a glass substrate, regardless of a depicted or actual orientation of the glass-encapsulated pressure sensor.) In the example of FIGS. 18A and 18B, the topside port 921 is centered in the cover glass 902, though in some other implementations, the topside port can be offset from the center of the cover glass 902. The dimensions and possible shapes of the topside port 921 are sufficient to allow fluid access to and equilibration at pressure sensor 908 and are discussed above with respect to FIGS. 17A and 17B.

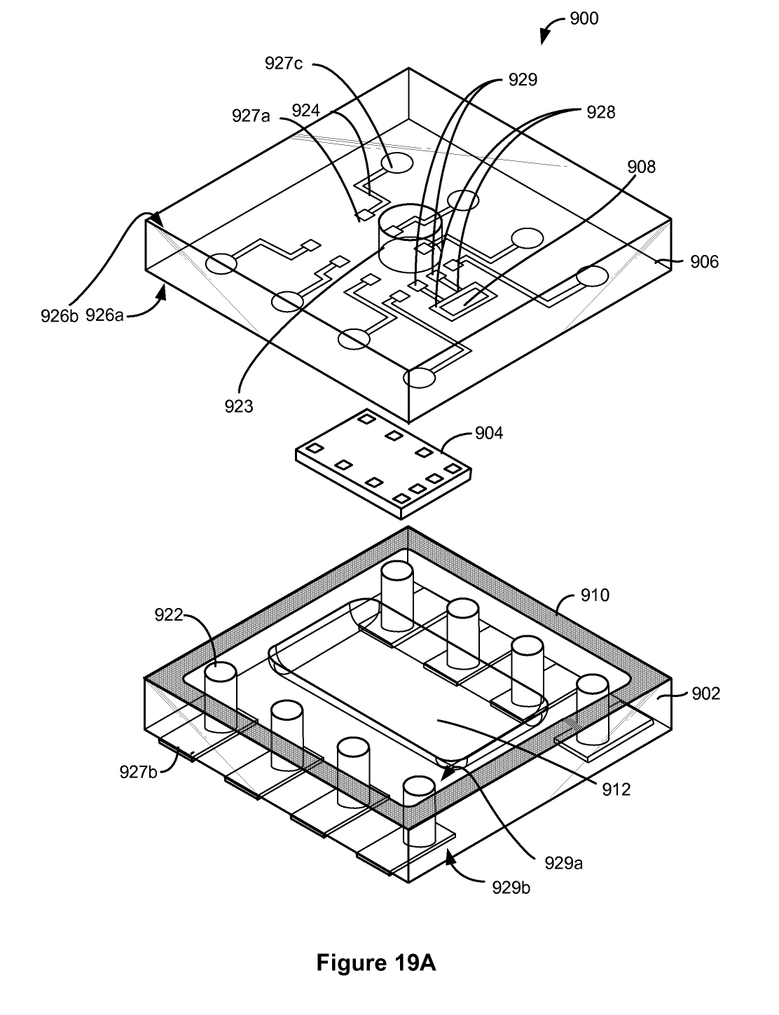

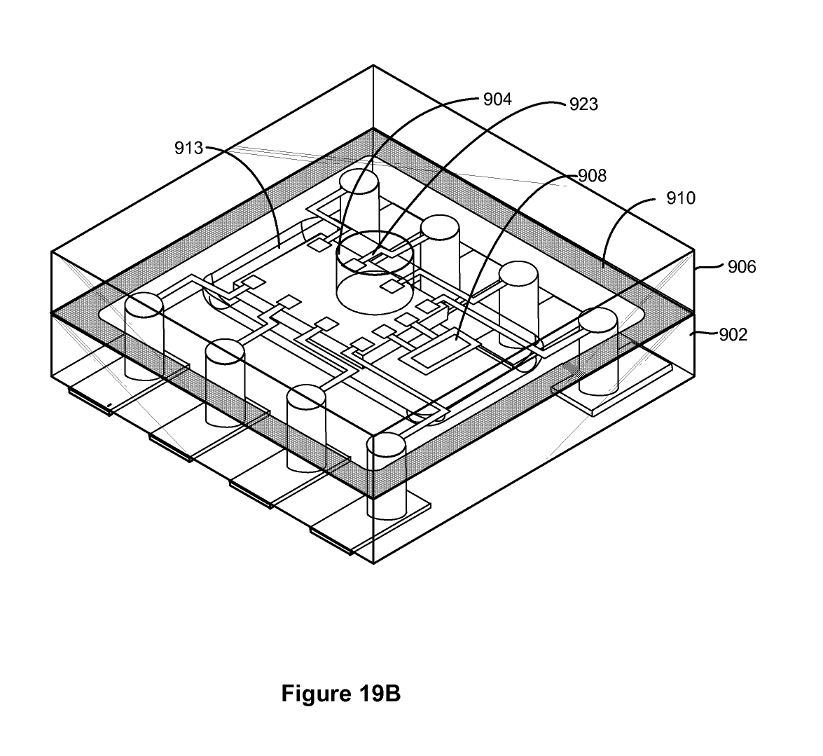

FIGS. 19A and 19B show examples of varying views of a glass-encapsulated pressure sensor including a port extending through a glass substrate. FIG. 19A shows an example of an exploded view diagram of the glass-encapsulated pressure sensor. FIG. 19B shows an example of a simplified isometric view of the glass-encapsulated pressure sensor shown in FIG. 19A. For clarity, some components shown in FIG. 19A are not shown in FIG. 19B. The glass-encapsulated pressure sensor 900 shown in FIGS. 19A and 19B includes a cover glass 902, an integrated circuit device 904, a glass substrate 906, an electromechanical pressure sensor 908, and a joining ring 910. For illustrative purposes, FIGS. 19A and 19B depict the glass-encapsulated pressure sensor 900 with the cover glass 902 on bottom and the glass substrate 906 on top.

The cover glass 902 is substantially planar, having two major substantially parallel surfaces, an interior surface 929a and an exterior surface 929b. A recess 912 is formed in the interior surface 929a as shown in the example of FIG. 19A. When the cover glass 902 is bonded to the glass substrate 906, a cavity 913 is formed by the recess 912 as depicted in the example of FIG. 16B. The cavity 913 accommodates the integrated circuit device 904 and the electromechanical pressure sensor 908. Through-glass vias 922 extend through the cover glass 902, providing a connection between the components in the interior of the glass-encapsulated pressure sensor 900 and bond pads 927b on the exterior surface 929b of the cover glass 902.

The glass substrate 906 has two major substantially parallel surfaces, an interior surface 926a and an exterior surface 926b. Bond pads 927c on the interior surface 926a provide a point of connection for through-glass vias 922 in cover glass 902. Conductive traces 924 on the interior surface 926a connect the bond pads 927c to bond pads 927a, which may be used for connections to the integrated circuit device 904. Conductive traces 928 connect the pressure sensor 908 to bond pads 929; the bond pads 929 may be used for connections to the integrated circuit device 904. Accordingly, conductive traces 924 and 928, bond pads 927a, 927b, 927c and 929, and through-glass vias 922 provide an electrical connection from the pressure sensor 908 to the exterior surface 929b of cover glass 902. The cover glass 902 is joined to the glass substrate 906 by joining ring 910 and metal solder that connects the through-glass vias 922 in the cover glass 902 to the bond pads 927c on the interior surface 926a of the glass substrate 906.

A bottomside port 923 extends through the glass substrate 906. The bottomside port 923 allows fluid access to the pressure sensor 908. In the example of FIGS. 19A and 19B, the bottomside port 923 is centered in the glass substrate 906. In this example as shown, the bottomside port 923 is centered under the integrated circuit device 904, with pressure ingress and egress allowed through small separations between the integrated circuit device 904 and the glass substrate 906. In some implementations, the bottomside port 923 can be offset from the center of the glass substrate 906. In some implementations, the bottomside port 923 can be directly underneath the pressure sensor 908, allowing for differential or gage pressure measurements. However, in implementations in which the pressure sensor 908 includes a reference cavity etched into the glass substrate 906, the bottomside port 923 is offset from the pressure sensor 908. The dimensions and shapes of the bottomside port 923 are sufficient to allow fluid access to and equilibration at pressure sensor 908. A glass-encapsulated pressure sensor including a port through a glass substrate also can include through-glass vias in a cover glass rather than a glass substrate. In some implementations, a second pressure port (not shown) may be incorporated in the top, bottom, or side of the glass package, or through the joining ring to allow differential or gage pressure sensor measurements.

In some implementations, a glass-encapsulated pressure sensor is configured to connect to a flexible connector. FIGS. 20A-21B show examples of varying views of a glass-encapsulated pressure sensor configured to connect to a flexible connector. FIG. 20A shows an example of an exploded view diagram of a glass-encapsulated pressure sensor configured to connect to a flexible connector. FIG. 20B shows an example of an isometric view of the glass-encapsulated pressure sensor shown in FIG. 20A. The glass-encapsulated pressure sensor 900 shown in FIGS. 20A and 20B includes a cover glass 902, an integrated circuit device 904, a glass substrate 906, an electromechanical pressure sensor 908, and a joining ring 910. The cover glass 902 includes a recess 912 and a topside port 921, as described above with respect to FIGS. 17A-18B. When the cover glass 902 is bonded to the glass substrate 906, a cavity 913 is formed by the recess 912. Different implementations of the cover glass 902 may be used, as described above.

The glass substrate 906 is generally a planar substrate having two substantially parallel surfaces, an interior surface 926a and an exterior surface 926b. A ledge 932 allows for electrical connections to portions of the interior surface 926a enclosed by the cover glass 902. Conductive traces 924 on the interior surface 926a connect bond pads 927a to ledge pads 927d. The bond pads 927a may be used for connections to the integrated circuit device 904. The electromechanical pressure sensor 908 and the integrated circuit device 904 may be electrically connected to one or more of the ledge pads 927d directly or indirectly by the traces 924 on the glass substrate 906. In the example of FIGS. 20A and 20B, conductive traces 928 connect the electromechanical pressure sensor 908 to bond pads 929 and the bond pads 929 may be used for connections to the integrated circuit device 904. The traces thus provide electrical connection from one or more bond pads, integrated circuit devices, electromechanical pressure sensors, or other components that may be enclosed by the cover glass to one or more ledge pads or other components. The particular arrangement of the traces, the bond pads, and the ledge pads associated with the glass substrate 906 is an example of one possible arrangement, with other arrangements possible. In some implementations, ledge pads may be disposed on a ledge formed by a cover glass extending past a glass substrate, for example.

In some implementations, portions of the conductive traces on the interior surface 926a that are exposed to the outside environment may be passivated. For example, the conductive traces may be passivated with a passivation layer, such as a coating of an oxide or a nitride.

The joining ring 910 bonds the cover glass 902 to the glass substrate 906. The joining ring may include any number of different bonding materials, as described above. In some implementations, when the joining ring 910 is a metal bond ring bonding the cover glass 902 to the glass substrate 906, the conductive traces 924 electrically connecting the bond pads 927a to the ledge pads 927d may be electrically insulated from the metal bond ring. For example, the conductive traces 924 may be electrically insulated by a passivation layer, as described above.

The glass-encapsulated pressure sensor 900 shown in the example of FIGS. 20A and 20B may further include or be connected to a flexible connector 940. A flexible connector also can be referred to as a ribbon cable, a flexible flat cable, or a flex tape. The flexible connector 940 may include a polymer film with embedded electrical connections, such as conducting wires or traces, running parallel to each other on the same flat plane. The flexible connector 940 also may include flex pads at one end, and contacts at the other end, with the conducting wires or traces electrically connecting individual flex pads with individual contacts. The flex pads may be configured to make contact with the ledge pads 927d. In some implementations, the flex pads of the flexible connector 940 may be bonded to the ledge pads of the glass-encapsulated pressure sensor 900 with an anisotropic conductive film (ACF). In some other implementations, the flex pads of the flexible connector 940 may be bonded to the ledge pads 927d of the glass-encapsulated pressure sensor 900 with solder. The contacts of the flexible connector 940 may be assembled in a socket or other connector, for example, for connection to a PCB or other electronic component.

In some implementations, the glass-encapsulated pressure sensor with a ledge 932 for connection to a flexible connector 940 may allow the glass-encapsulated pressure sensor to be located away from a PCB or other electronic component. When the glass-encapsulated pressure sensor 900 is located away from a PCB or other electronic component, the PCB may be enclosed within a liquid-resistant enclosure, improving the reliability of the electronic device incorporating the glass-encapsulated pressure sensor and the PCB. The use of a flexible connector also can obviate the need for electrical vias through the glass substrate or cover glass, which may simplify the fabrication processes for a glass-encapsulated pressure sensor.

FIG. 21A shows another example of an exploded view diagram of a glass-encapsulated pressure sensor configured to connect to a flexible connector. FIG. 21B shows an example of an isometric view of the glass-encapsulated pressure sensor shown in FIG. 21A.

The glass-encapsulated pressure sensor 900 shown in FIGS. 21A and 21B includes a cover glass 902, an integrated circuit device 904, a glass substrate 906, an electromechanical pressure sensor 908, and a joining ring 910. The cover glass 902 includes a recess 912, including a main portion 912a and a narrow portion 912b as described above with respect to FIGS. 9A-10B. When the cover glass 902 is bonded to the glass substrate 906, a cavity 913 is formed by the recess 912 and a port is formed by the narrow portion 912b of the recess 912. Different implementations of the cover glass 902 may be used, as described above.

The glass substrate 906 has an interior surface 926a, an exterior surface 926b, and a ledge 932 on which ledge pads 927d can be formed. As discussed above with respect to FIGS. 20A and 20B, the ledge 932 extends past the cover glass 902 when the glass substrate 906 is bonded to the cover glass 902. Conductive traces 924 and 928 and bond pads 929 and 927a can provide an electrical connection between the pressure sensor 908 and the ledge pads 927d. The integrated circuit device 904, which can be attached to the glass substrate 906 by flip-chip attachment to bond pads 927a and 929, also can be connected to ledge pads 927d by bond pads 927a and conductive traces 924. In the example of FIGS. 21A and 21B, a flexible connector 940 is attached to the glass-encapsulated pressure 900 also as described above with respect to FIGS. 20A and 20B.

In some implementations, one or more integrated circuit devices can be attached to a flat flexible connector apart from the glass-encapsulated pressure sensor package. For example, one or more chip scale package (CSP) silicon dies for signal conditioning and formatting can be attached to the flexible connector 940. In some implementations, this can allow further reduction of the dimensions of the glass-encapsulated pressure sensor package, as it allows the integrated circuit devices to be positioned on the flexible connector rather than inside the package.

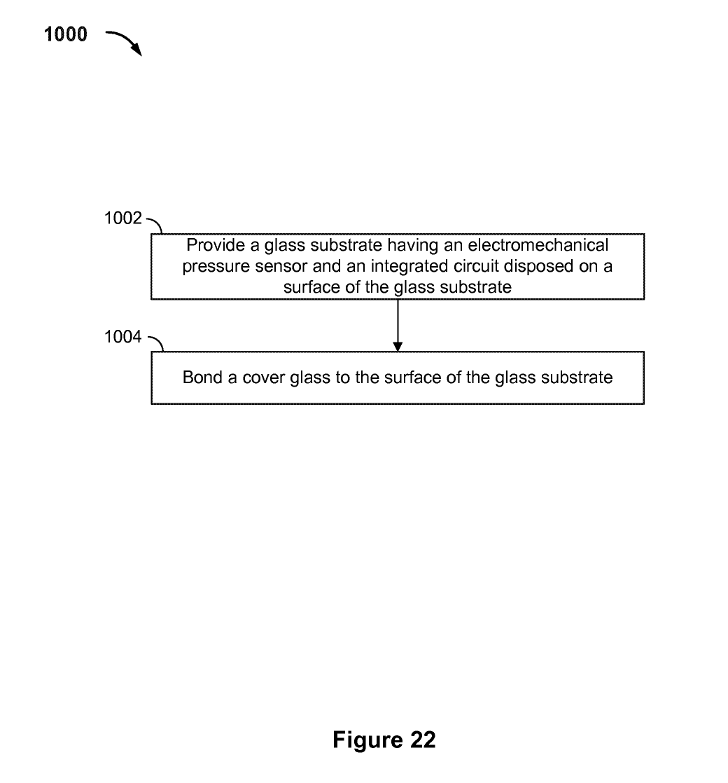

FIG. 22 shows an example of a flow diagram illustrating a manufacturing process for a glass-encapsulated pressure sensor. At block 1002 of the process 1000, a glass substrate having an electromechanical pressure sensor and an integrated circuit device disposed on a surface of the glass substrate is provided. The glass substrate also may include conductive traces and bond pads, similar to the glass substrate 906 shown in FIG. 10A, for example. In some implementations, the glass substrate also may include through-glass vias, similar to the glass substrate 906 shown in FIG. 11A, for example.

In some implementations, the glass substrate may include ledge pads, similar to the glass substrate 906 shown in FIGS. 20A and 21A, for example. Conductive traces and bond pads may be formed by any appropriate process including CVD, PVD, electroplating or electroless plating, for example.

In some implementations, the glass substrate may include one or more ports, similar to the glass substrate 906 shown in FIG. 19A, for example. A port may be formed in glass substrate with a chemical etching process, laser or focused ion beam ablation process, or a sandblasting process. The integrated circuit device may be configured to sense output from the electromechanical pressure sensor. Electrical components such as conductive traces, bond pads and through-glass vias, if present, may be formed before, after or during fabrication of a pressure sensor on the glass substrate.

At block 1004, a cover glass is bonded to the surface of the glass substrate. Examples of cover glasses are described above, in FIGS. 9A-21B. Recesses and ports in a cover glass may be formed, for example, with a chemical etching process or a sandblasting process.

As described above, the cover glass may be bonded to the glass substrate with a joining ring that may include any number of different bonding materials. In some implementations, the cover glass is bonded to the glass substrate with an adhesive. In some implementations, the cover glass is bonded to the glass substrate with a UV curable epoxy or a heat-curable epoxy. When epoxy is used to bond the cover glass to the glass substrate, the epoxy may be screened or dispensed around the edges of the cover glass or the glass substrate. Then, the cover glass and the glass substrate may be aligned and pressed together and UV light or heat applied to the epoxy to cure the epoxy.

In some other implementations, the cover glass is bonded to the glass substrate with a glass frit bond ring. Glass frit may be applied to the glass substrate, cover glass, or both using dispensing, shadow masking, or other appropriate technique. When a glass frit bond ring is used to bond the cover glass to the glass substrate, heat and pressure may be applied to the cover glass, the glass substrate, and the glass frit bond ring when these components are in contact with one another such that glass frit bond ring melts and bonds the two glass pieces together.

In some other implementations, the cover glass is bonded to the glass substrate with a metal bond ring. When a metal bond ring is used to bond the cover glass to the glass substrate, heat may be applied to the cover glass, the glass substrate, and the metal bond ring when these components are in contact with one another such that metal bond ring melts and bonds the two glass pieces together.

While the process 1000 describes a manufacturing process for a glass-encapsulated pressure sensor, a plurality of glass-encapsulated pressure sensors may be manufactured with the process 1000. For example, a glass substrate may include a plurality of electromechanical pressure sensors and integrated circuit devices. Likewise, the cover glass may include a plurality of recesses. The cover glass may be bonded to the surface of the glass substrate, forming a sheet of glass-encapsulated pressure sensors. The glass-encapsulated pressure sensors may be then separated from one another. The glass-encapsulated pressure sensors may be separated from one another using a dicing process employing a diamond blade or a laser, a scribe and break process, or other appropriate process to cut the cover glass and the glass substrate.

Further description of features of glass packages and methods of fabrication that may be implemented in accordance with glass-encapsulated pressure sensors described herein can be found in co-pending U.S. patent application Ser. Nos. 13/221,701, 13/221,717, and 13/221,744, each entitled “Glass as a Substrate Material and a Final Package for MEMS and IC Devices,” filed Aug. 30, 2011, and incorporated by reference herein.

In some other implementations, pressure sensors fabricated on glass substrates can be compatible with displays and other devices that are also fabricated on glass substrates, with the non-display devices fabricated jointly with a display device or attached as a separate device, the combination having well-matched thermal expansion properties.

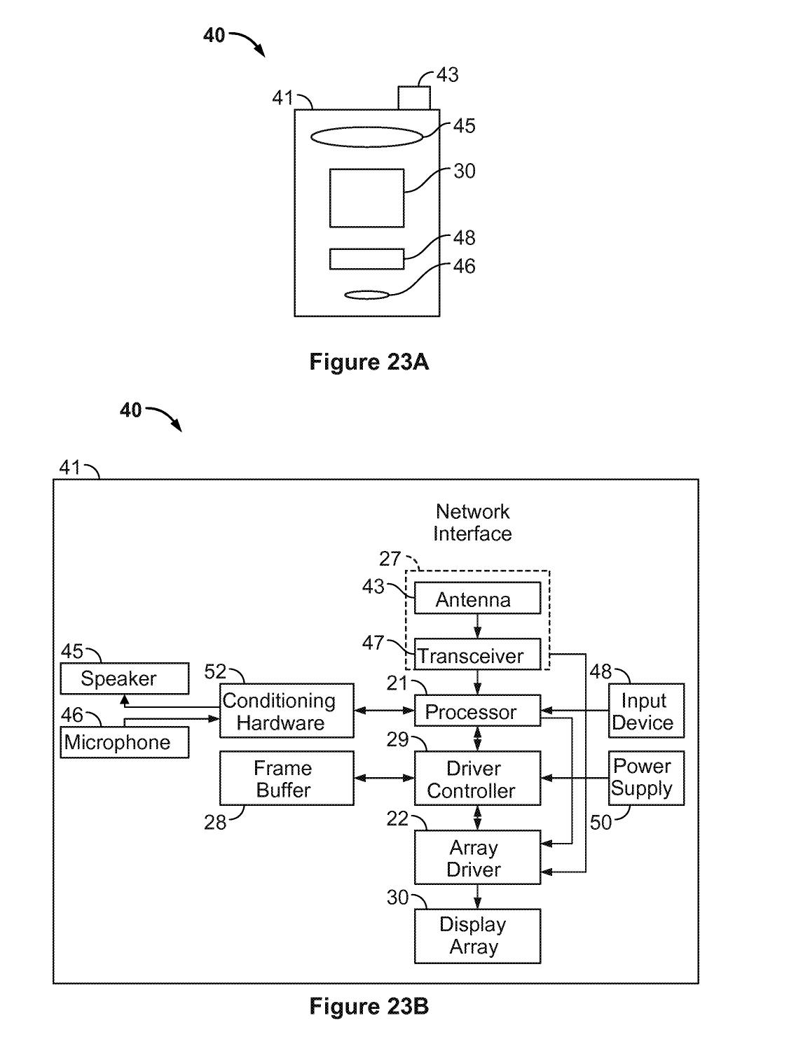

FIGS. 23A and 23B show examples of system block diagrams illustrating a display device 40 that includes a plurality of IMODs. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 23B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a glass substrate;
an electromechanical pressure sensor disposed on a surface of the glass substrate;
a cover glass bonded to the surface of the glass substrate with a joining ring, wherein the cover glass includes a first recess that forms a first cavity when the cover glass is bonded to the surface of the glass substrate, the first cavity being configured to accommodate the electromechanical pressure sensor, and
a port in at least one of the glass substrate, joining ring, or cover glass providing fluidic access to the pressure sensor.

2. The apparatus of claim 1, further comprising an integrated circuit device disposed on the surface of the glass substrate, the integrated circuit device configured to sense output from the electromechanical pressure sensor.

3. The apparatus of claim 2, wherein the first cavity is further configured to accommodate the integrated circuit device.

4. The apparatus of claim 2, wherein the cover glass further includes a second recess that forms a second cavity when the cover glass is bonded to the surface of the glass substrate, the second cavity being configured to accommodate the integrated circuit device.

5. The apparatus of claim 4, wherein the second cavity is isolated from the first cavity by the joining ring.

6. The apparatus of claim 4, wherein the second cavity is hermetically sealed.

7. The apparatus of claim 1, wherein the port is partially defined by the first recess.

8. The apparatus of claim 1, wherein the port is partially defined by one or more channels in the joining ring.

9. The apparatus of claim 1, further comprising a feature in the port partially obstructing fluid access to the pressure sensor.

10. The apparatus of claim 1, wherein the cover glass bonded to the glass substrate forms a glass die having a plurality of side surfaces and further wherein the port is in one of the plurality of side surfaces.

11. The apparatus of claim 1, wherein the cover glass bonded to the glass substrate forms a glass die having a plurality of side surfaces disposed between parallel major surfaces of the glass substrate and cover glass, and wherein the port is in one of the parallel major surfaces.

12. The apparatus of claim 1, further comprising through-glass via interconnects in at least one of the cover glass and the glass substrate.

13. The apparatus of claim 1, wherein the joining ring includes at least one of a metal bond ring, an epoxy, or a glass frit.

14. The apparatus of claim 1, wherein a thickness of the glass substrate is about 50 to 700 microns, and wherein a thickness of the cover glass is about 50 to 700 microns.

15. The apparatus of claim 1, wherein the port has a smallest dimension of between about 0.2 microns and 300 microns.

16. The apparatus of claim 1, wherein the glass substrate and the cover glass serve as packaging for the electromechanical pressure sensor.

17. The apparatus of claim 1, further comprising a plurality of bond pads on a surface of the cover glass or the glass substrate configured to attach to a flexible connector.

18. The apparatus of 17, wherein the bond pads are on a ledge formed by the glass substrate extending past a side surface of the cover glass.

19. The apparatus of claim 17, wherein the bond pads are on a ledge formed by the cover glass extending past a side surface of the glass substrate.

20. The apparatus of claim 17, further comprising:
a flexible connector, the flexible connector including:
a plurality of flex pads at a first end of the flexible connector;
a plurality of contacts at a second end of the flexible connector; and
a plurality of electrical connections connecting each of the plurality of flex pads with a contact of the plurality of contacts,
wherein each of the plurality of flex pads is in electrical contact with a bond pad of the plurality of bond pads.

21. The apparatus of claim 1, wherein the cover glass further includes a second recess that forms a second cavity when the cover glass is bonded to the surface of the glass substrate.

22. The apparatus of claim 1, further comprising:
a display;
a processor that is configured to communicate with the display, the processor being configured to process image data; and
a memory device that is configured to communicate with the processor.

23. The apparatus of claim 22, further comprising:
a driver circuit configured to send at least one signal to the display; and
a controller configured to send at least a portion of the image data to the driver circuit.

24. The apparatus of claim 23, further comprising:
an image source module configured to send the image data to the processor, wherein the image source module includes at least one of a receiver, transceiver, and transmitter.

25. The apparatus of claim 22, further comprising:
an input device configured to receive input data and to communicate the input data to the processor.

26. An apparatus comprising:
means for encapsulating an electromechanical pressure sensor inside a package;
means for transmitting a fluidic pressure from an outside of the package to the electromechanical pressure sensor;
means for converting a fluidic pressure within the electromechanical pressure sensor into an electrical signal; and
means for transmitting an electrical signal from the electromechanical pressure sensor to the exterior of the package.

27. The apparatus of claim 26, further comprising means for conditioning the electrical signal generated by the electromechanical pressure sensor.

28. The apparatus of claim 26, further comprising means for hermetically sealing an integrated circuit device encapsulated inside the package.

29. A method comprising:
providing a glass substrate, the glass substrate having an electromechanical pressure sensor and an integrated circuit device disposed on a surface of the glass substrate, the integrated circuit device configured to sense output from the electromechanical pressure sensor; and
bonding a cover glass to the surface of the glass substrate, wherein the cover glass includes a first recess that forms a first cavity when the cover glass is bonded to the surface of the glass substrate, the first cavity being configured to accommodate the electromechanical pressure sensor.

30. The method of claim 29, wherein a portion of the first recess is at an edge of the cover glass such that when the cover glass is bonded to the surface of the glass substrate, a port is formed, the port configured to allow a pressure signal to interact with the electromechanical pressure sensor.

31. The method of claim 29, wherein the bonding is performed with at least one of a metal bond ring or an epoxy.
